(19) United States
(12) Patent Application Publication
(10) Pub. No.: US 2025/0322775 A1
(43) Pub. Date: Oct. 16, 2025

(54) METHOD OF PREDICTING LIFESPAN OF DISPLAY DEVICE

(71) Applicant: Samsung Display Co., LTD., Yongin-si (KR)

(72) Inventors: Hee Kwang SONG, Yongin-si (KR); Joon Hyuk YANG, Yongin-si (KR)

(73) Assignee: Samsung Display Co., LTD., Yongin-si (KR)

(21) Appl. No.: 19/014,372

(22) Filed: Jan. 9, 2025

(30) Foreign Application Priority Data
Apr. 11, 2024 (KR) 10-2024-0048530

(51) Int. Cl. G09G 3/00; H10K 59/38; H10K 71/00

(52) U.S. Cl. CPC G09G 3/006; H10K 59/38; H10K 71/831; G09G 2330/12

(57) ABSTRACT

A method of predicting a lifespan of a display device includes preparing a test panel including a test light emitting element including a first and second test light emitting layers, measuring a luminance of the first and second color of the test panel to acquire first and second deterioration data of the first and second color, calculating a lifespan of a pixel based on the first and second deterioration data, and a first and second color component ratio of first emission light for a thickness of a wavelength conversion layer. The pixel includes a light emitting element emitting the first emission light and mixed light of the first and second color, and the wavelength conversion layer, and a light emitting layer of the light emitting element includes a first light emitting layer emitting light of the first color, and a second light emitting layer emitting light of the second color.

### CROSS-REFERENCE TO RELATED APPLICATION(S)

This application claims priority to and benefits of Korean Patent Application No. 10-2024-0048530 under 35 U.S.C. 119, filed on April 11,2024, in the Korean Intellectual Property Office (KIPO), the entire contents of which are incorporated herein by reference.

### BACKGROUND

### 1. Technical Field

The disclosure relates to a method of predicting a lifespan of a display device.

### 2. Description of the Related Art

The importance of display devices has steadily increased with the development of multimedia technology. Along with this trend, various types of display devices such as a liquid crystal display (LCD) device, an organic light emitting diode (OLED) display device and the like have been developed.

Among the display devices, a self-light emitting display device includes a self-light emitting element such as an organic light emitting element. The self-light emitting element may include two opposite electrodes and a light emitting layer interposed between the electrodes. In the case of using the organic light emitting element as the self-light emitting element, the electrons and holes from the two electrodes are recombined in the light emitting layer to produce excitons, which transition from the excited state to the ground state, emitting light.

The display device may include a color conversion element that implements color by receiving light from an organic light emitting element or the like. For example, the color conversion element receives blue light from the organic light emitting element and emits blue, green, and red colors, respectively, so that images having various colors may be visually recognized. The color conversion element may be disposed on a display device in the form of a separate substrate or may be formed by being directly integrated with elements in the display device.

The lifespan of the display device may be determined not only by the organic light emitting element but also by the color conversion element.

### SUMMARY

Aspects of the disclosure provide a method of predicting a lifespan of a display device with a reduced lifespan evaluation time and a small error rate.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a method of predicting a lifespan of a display device may include preparing a test panel comprising a test light emitting element comprising a first test light emitting layer which emits light of a first color and a second test light emitting layer which emits light of a second color different from the first color, measuring a luminance of the light of the first color and a luminance of the light of the second color of the test panel during a measurement period to acquire first deterioration data of the first color and second deterioration data of the second color, calculating a lifespan of a first pixel of a display device different from the test panel based on the first deterioration data, the second deterioration data, and a first color component ratio and a second color component ratio of first emission light for a thickness of a first wavelength conversion layer. The first pixel of the display device may include a first light emitting element which emits the first emission light and mixed light of the first color and the second color, and the first wavelength conversion layer overlapping the first light emitting element in a thickness direction, and a light emitting layer of the first light emitting element may include a first light emitting layer which emits light of the first color, and a second light emitting layer which emits light of the second color and overlaps the first light emitting layer in the thickness direction.

The test light emitting element may include a plurality of first test light emitting layers overlapping each other in the thickness direction, the light emitting layer of the first light emitting element may include a plurality of first light emitting layers overlapping each other in the thickness direction, and a number of the plurality of first test light emitting layers comprised in the test light emitting element and a number of the plurality of first light emitting layers comprised in the light emitting layer of the first light emitting element may be equal.

The first color may be blue and the second color may be green or red.

The test light emitting element may further include a third test light emitting layer which emits light of a third color different from the first color and the second color, the first light emitting element may emit mixed light of the first color, the second color, and the third color, the light emitting layer of the first light emitting element may further include a third light emitting layer which emits light of the third color, and the first color may be blue, the second color may be green, and the third color may be red.

Each of the first color component ratio and the second color component ratio of the first emission light may be less than 1.

A sum of the first color component ratio and the second color component ratio of the first emission light may be 1.

As the thickness of the first wavelength conversion layer decreases, the first color component ratio of the first emission light may decrease.

The first color component ratio and the second color component ratio of the first emission light may be determined by a wavelength conversion shifter of the first wavelength conversion layer and a color filter disposed on the first wavelength conversion layer.

The measuring of the luminance of the light of the first color and the luminance of the light of the second color of the test panel during the measurement period to acquire the first deterioration data of the first color and the second deterioration data of the second color may include disposing a color filter of the first color on the test light emitting element and measuring a luminance of the light of the first color that changes during the measurement period to acquire the first deterioration data which is a luminance maintenance rate compared to an initial luminance of the light of the first color, and disposing a color filter of the second color on the test light emitting element, and measuring a luminance of the light of the second color that changes during the measurement period to acquire the second deterioration data which is a luminance maintenance rate compared to an initial luminance of the light of the second color.

The calculating of the lifespan of the first pixel of the display device may include calculating correction deterioration data using Equation 1:

LEX=LC1×M1+LC2×M2 [Equation 1]
wherein LEX may be a corrected luminance maintenance rate of the first pixel, LC1 may be a luminance maintenance rate in the first deterioration data, LC2 may be a luminance maintenance rate in the second deterioration data, M1 may be the first color component ratio of the first emission light, and M2 may be the second color component ratio of the first emission light, and determining, from the correction deterioration data, a time at which the luminance maintenance rate falls below a preset ratio as the lifespan of the first pixel.

The method of predicting the lifespan of the display device may further include calculating lifespans of the first pixel of the display device by varying the thickness of the first wavelength conversion layer, and selecting an optimal lifespan among the lifespans of the first pixel.

The light emitting layer of the first light emitting element may include a first hole transport layer, a first stack in which the first light emitting layer and a first electron transport layer are sequentially disposed, and a second stack in which a second hole transport layer, the second light emitting layer and a second electron transport layer are sequentially disposed, and the first stack and the second stack may overlap each other in the thickness direction.

The light emitting layer of the first light emitting element may include a plurality of first stacks, and the plurality of first stacks and the second stack may overlap each other in the thickness direction.

The method of predicting the lifespan of the display device may further include calculating a lifespan of a second pixel of the display device based on the first deterioration data, the second deterioration data, and the first color component ratio and the second color component ratio of second emission light for a thickness of a second wavelength conversion layer. The second pixel of the display device may include a second light emitting element which emits the second emission light and mixed light of the first color and the second color, and a second wavelength conversion layer overlapping the second light emitting element in the thickness direction.

The second color component ratio of the second emission light may be greater than the second color component ratio of the first emission light.

The method of predicting the lifespan of the display device may further include calculating a lifespan of a third pixel of the display device based on the first deterioration data, the second deterioration data, and the first color component ratio and the second color component ratio of third emission light for a thickness of a light transmitting layer. The third pixel of the display device may include a third light emitting element which emits the third emission light and mixed light of the first color and the second color, and the light transmitting layer overlapping the third light emitting element in the thickness direction.

The second color component ratio of the third emission light may be smaller than the second color component ratio of the first emission light.

The first wavelength conversion layer may include a first base resin and a first wavelength conversion shifter, the second wavelength conversion layer may include a second base resin and a second wavelength conversion shifter, and the light transmitting layer may include a third base resin.

The display device may include a first color filter disposed on the first wavelength conversion layer, a second color filter disposed on the second wavelength conversion layer, and a third color filter disposed on the light transmitting layer, the first color filter may pass light of a third color different from the first color and the second color, the second color filter may pass the light of the second color, and the third color filter may pass the light of the first color.

The first emission light may include a component of light converted from the light of the first color, which passes through the first color filter; and a component of the light of the second color, which passes through the first color filter.

An electronic comprising: at least one display device including a substrate having cross-repeated planar and tower areas; and at least one of a display module, a processor, a memory, and a power module connected to the display device, a method of predicting a lifespan of the display device, comprising: preparing a test panel comprising a test light emitting element comprising a first test light emitting layer which emits light of a first color and a second test light emitting layer which emits light of a second color different from the first color; measuring a luminance of the light of the first color and a luminance of the light of the second color of the test panel during a measurement period to acquire first deterioration data of the first color and second deterioration data of the second color; calculating a lifespan of a first pixel of a display device different from the test panel based on the first deterioration data, the second deterioration data, and a first color component ratio and a second color component ratio of first emission light for a thickness of a first wavelength conversion layer, wherein the first pixel of the display device comprises a first light emitting element which emits the first emission light and mixed light of the first color and the second color, and the first wavelength conversion layer overlapping the first light emitting element in a thickness direction, and a light emitting layer of the first light emitting element comprises a first light emitting layer which emits light of the first color, and a second light emitting layer which emits light of the second color and overlaps the first light emitting layer in the thickness direction.

According to the method of predicting a lifespan of a display device according to one embodiment, the lifespan of the display device may be predicted without manufacturing a sample of the display device including a light emitting portion, a light transmitting portion, and a color filter portion.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a flowchart illustrating a method for predicting a lifespan of a display device according to one embodiment;

FIG. 2 is a perspective view showing a display device according to one embodiment;

FIG. 3 is a schematic cross-sectional view of a display device taken along line X1-X1′ of FIG. 2;

FIG. 4 is a plan view of a display area of a display device according to one embodiment;

FIG. 5 is a schematic cross-sectional view of a display device taken along line X2-X2′ of FIG. 4;

FIG. 6 is an enlarged view of area A1 in FIG. 5;

FIG. 7 is a schematic cross-sectional view illustrating a test panel according to one embodiment;

FIG. 8 is a graph showing first deterioration data and second deterioration data in first to third pixels of the test panel according to one embodiment;

FIG. 9 is a graph showing correction deterioration data in the first pixel;

FIG. 10 is a graph showing a comparison between correction deterioration data of FIG. 9;

FIG. 11 is a graph showing a lifespan error rate of the display device in which the correction deterioration data is not reflected; and

FIG. 12 is a graph showing a lifespan error rate of the display device in which afterimages are corrected through the correction deterioration data.

FIG. 13 is a block diagram of an electronic device according to one embodiment of the present disclosure.

FIG. 14 is a schematic diagram of an electronic device according to various embodiments of the present disclosure.

### DETAILED DESCRIPTION OF THE EMBODIMENTS

The disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

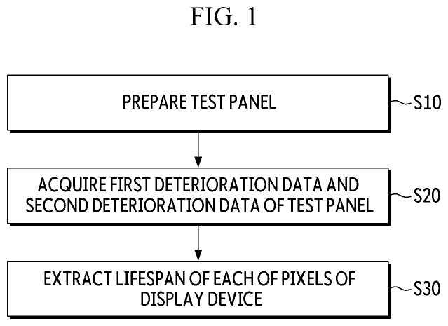

FIG. 1 is a flowchart illustrating a method for predicting a lifespan of a display device according to one embodiment.

Referring to FIG. 1, the method of predicting a lifespan of a display device 1 may include preparing a test panel 1000 (step S10), acquiring first deterioration data of a first color and second deterioration data of a second color emitted from the test panel 1000 (step S20), and extracting a lifespan of each of the pixels of the display device based on a first color component ratio, a second color component ratio, first deterioration data, and second color deterioration data (step S30).

First, the display device 1 will be described in detail.

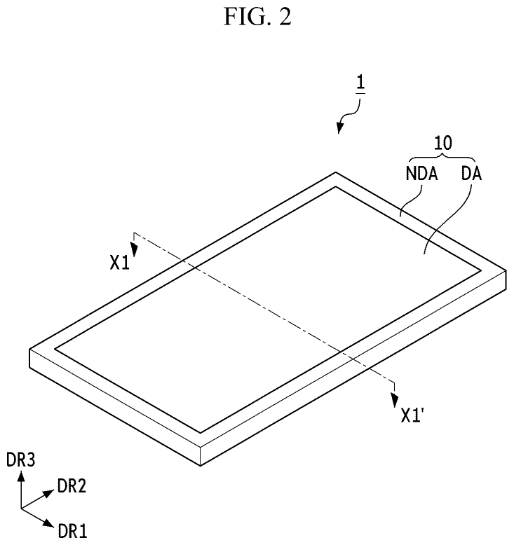

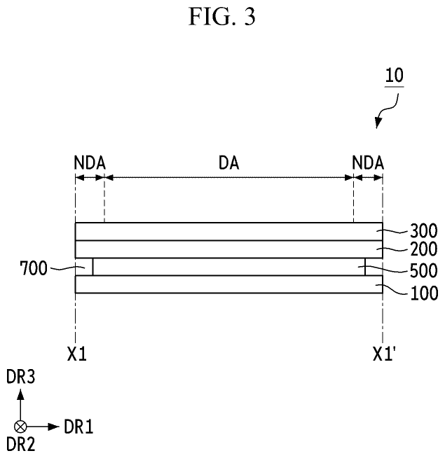

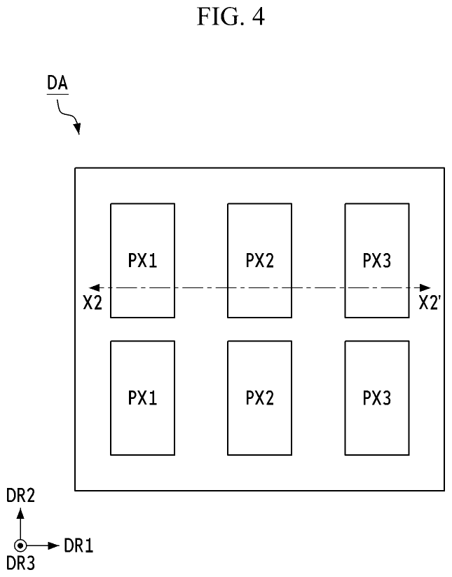

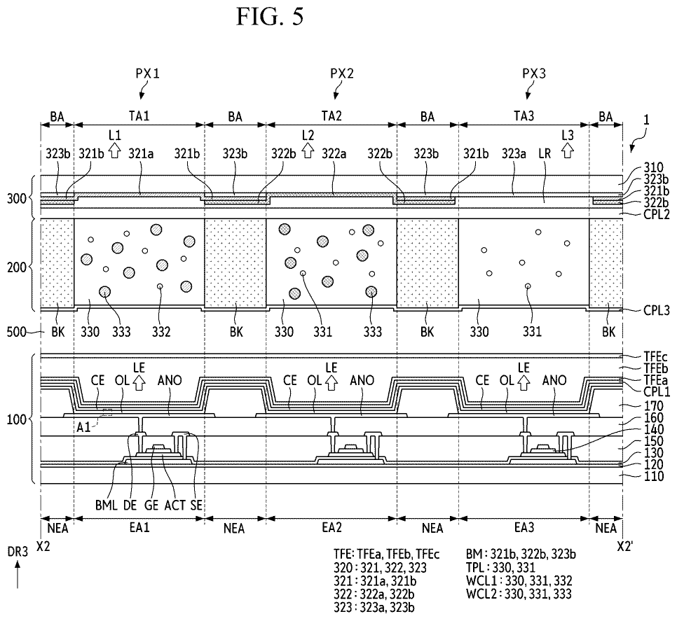

FIG. 2 is a perspective view showing a display device according to one embodiment. FIG. 3 is a schematic cross-sectional view of a display device taken along line X1-X1′ of FIG. 2. FIG. 4 is a plan view of a display area of a display device according to one embodiment. FIG. 5 is a schematic cross-sectional view of a display device taken along line X2-X2′ of FIG. 4.

Referring to FIG. 2, the display device 1 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. In another embodiment, the display device 1 according to one embodiment may be applied as a display unit of a television, a laptop, a monitor, a billboard, or an Internet-of-Things (IoT) terminal. However, the disclosure is not limited thereto, and the display device 1 may be applied to other electronic devices without departing from the disclosure.

In FIG. 2, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. The first direction DR1 may be a horizontal direction in the drawing, the second direction DR2 may be a vertical direction in the drawing, and the third direction DR3 may be an upward and downward direction (i.e., a thickness direction) in the drawing. In the following specification, unless otherwise stated, “direction” may refer to both of directions extending in the direction. Further, when it is necessary to distinguish both “directions” extending in both sides, a side will be referred to as “a side in the direction” and another side will be referred to as “another side in the direction.” Referring to FIG. 2, a direction in which an arrow is directed is referred to as a side, and the opposite direction is referred to as another side. Also, the third direction DR3 may be referred to as a thickness direction.

Hereinafter, for simplicity of description, when referring to the display device 1 or the surfaces of each member constituting the display device 1, a surface facing to a side in the direction in which the image is displayed, for example, the third direction DR3 is referred to as a top surface, and an opposite surface of the surface is referred to as a bottom surface. However, the disclosure is not limited thereto, and the surface and the another surface of the member may be referred to as a front surface and a rear surface, respectively. In describing the relative position of each of the members of the display device 1, a side of the third direction DR3 may be referred to as an upper side and another side of the third direction DR3 may be referred to as a lower side.

The display device 1 may have a three-dimensional shape. For example, the display device 1 may have a rectangular parallelepiped shape or a three-dimensional shape similar thereto. In one embodiment, the display device 1 according to one embodiment may have a shape similar to a quadrilateral shape in a plan view. In other words, the display device 1 according to one embodiment may have a shape similar to a quadrilateral shape having short sides in the first direction DR1 and long sides in the second direction DR2, as shown in FIG. 1, but is not limited thereto. For example, in a planar shape of the display device 1 according to one embodiment, a corner at which a short side in the first direction DR1 and a long side in the second direction DR2 meet may be formed to be rounded and have a curvature or may be formed at a right angle. The planar shape of the display device 1 is limited to a quadrilateral shape, and may be a shape similar to another polygonal shape, a circular shape, or an elliptical shape.

The display device 1 may include a display panel 10, a flexible circuit board, and a driving chip. The display panel may include a display area DA in which an image is displayed and a non-display area NDA in which an image is not displayed. In one embodiment, the non-display area NDA may surround the edge of the display area DA, but the disclosure is not limited thereto. An image displayed in the display area DA may be viewed by a user on a side in the third direction DR3 with reference to FIG. 2.

As shown in FIG. 3, the display panel 10 may include a light emitting portion 100, a light transmitting portion 200 disposed on the light emitting portion 100, and a color filter portion 300 disposed on the light transmitting portion 200, and may further include a sealing member 700 that combines the light transmitting portion 200 with the light emitting portion 100, and a filling portion 500 filled between the light transmitting portion 200 and the light emitting portion 100.

The light emitting portion 100 may include elements and circuits for displaying an image, for example, a pixel circuit such as a switching element, a pixel defining film 170 (see FIG. 5) and a self-light emitting element that define emission areas EA1, EA2, and EA3 and a non-emission area NEA (see FIG. 5), which will be described below, in the display area DA. In an embodiment, the self-light emitting element may include at least one of an organic light emitting diode, a quantum dot light emitting diode, an inorganic material-based micro light emitting diode (e.g., micro LED), and an inorganic material-based light emitting diode having a nano size (e.g., nano LED). Hereinafter, for simplicity of description, an embodiment that the self-light emitting element is an organic light emitting element will be described.

The light transmitting portion 200 may be located on the light emitting portion 100. In one embodiment, the light transmitting portion 200 may include a color conversion pattern for converting a color of incident light emitted from the light emitting portion 100 and irradiated to the light transmitting portion 200. In one embodiment, the color filter portion 300 may include a light transmitting member WCL1, WCL2, and TPL (see FIG. 5) to be described below as the color conversion pattern, and a bank pattern BK (see FIG. 5) surrounding the light transmitting member. The light transmitting member may include at least one of a wavelength conversion shifter and a light scatterer, as will be described below.

The color filter portion 300 may be located on the light transmitting portion 200. In one embodiment, the color filter portion 300 may include first to third color filters, and may optionally further include a black matrix.

The sealing member 700 may be located between the light transmitting portion 200 and the light emitting portion 100 in the non-display area NDA. The sealing member 700 may be disposed along edges of light transmitting portion 200 and the light emitting portion 100 in the non-display area NDA to surround the display area DA in a plan view. The light transmitting portion 200 and the light emitting portion 100 may be coupled to each other via the sealing member 700.

In one embodiment, the sealing member 700 may be made of an organic material. For example, the sealing member 700 may be made of an epoxy-based resin, but is not limited thereto. In another embodiment, the sealing member 700 may be applied in a form of a frit including glass or the like.

The filling portion 500 may be located in a space surrounded by the sealing member 700 between the light transmitting portion 200 and the light emitting portion 100. The filling portion 500 may fill the space between the light transmitting portion 200 and the light emitting portion 100.

In one embodiment, the filling portion 500 may be made of a material that can transmit light. In one embodiment, the filling portion 500 may be made of an organic material. For example, the filling portion 500 may be made of a silicone-based organic material, an epoxy-based organic material, a mixture of a silicone-based organic material and an epoxy-based organic material, or the like.

Hereinafter, the emission area and the non-emission area defined in the display area DA of the display panel 10 will be described in more detail.

Referring to FIG. 4, multiple pixels PX1, PX2, and PX3 may be disposed in the display area DA of the display device 1 according to one embodiment. Each of the pixels PX1, PX2, and PX3 may emit one of the first to third emission lights, and the first to third emission lights may be light that is emitted from the first to third emission areas EA1, EA2, and EA3 described below and passes through the light transmitting portion 200 and the color filter portion 300.

In one embodiment, as illustrated in FIG. 4, the first to third pixels PX1, PX2, and PX3 may be sequentially disposed in the first direction DR1, and the first pixel PX1 may be provided in plural and disposed in the second direction DR2. The first to third pixels PX1, PX2, and PX3 may form one group, and the group may be repeatedly disposed in the first direction DR1 and the second direction DR2 in the display area DA, but the disclosure is not limited thereto. Hereinafter, for simplicity of description, an embodiment that the first to third pixels PX1, PX2, and PX3 are disposed as illustrated in FIG. 4 will be described.

In one embodiment, the area of the first pixel PX1, the area of the second pixel PX2, and the area of the third pixel PX3 may be substantially the same in a plan view, but are not limited thereto. In another embodiment, the area of the first pixel PX1, the area of the second pixel PX2, and the area of the third pixel PX3 may be different. In one embodiment, the first to third pixels PX1, PX2, and PX3 may have a rectangular shape in a plan view, but are not limited thereto. Hereinafter, for simplicity of description, the description will made on an embodiment that that the first to third pixels PX1, PX2, and PX3 have a rectangular planar shape and have substantially a same area in a plan view.

Referring to FIG. 5, in the light emitting portion 100 of the display area DA, the first to third emission areas EA1, EA2, and EA3 corresponding to the first to third pixels PX1, PX2, and PX3 may be defined. The first emission area EA1, the second emission area EA2, and the third emission area EA3 may be areas in which light generated by the light emitting element of the light emitting portion 100 is emitted to the outside of the light emitting portion 100, and the non-emission area NEA may be an area in which light is not emitted to the outside of the light emitting portion 100. In one embodiment, the non-emission area NEA may surround the first emission area EA1, the second emission area EA2, and the third emission area EA3 in the display area DA in a plan view, but is not limited thereto.

In one embodiment, light LE emitted from the first emission area EA1, the second emission area EA2, and the third emission area EA3 of the light emitting portion 100 may be the same. The light LE emitted from the first to third emission areas may be blue light or mixed light. The mixed light may be light obtained by mixing two or more of blue light, green light, red light, and yellow light. Red light may have a peak wavelength in a range of about 610 nm to 650 nm, green light may have a peak wavelength in a range of about 510 nm to 550 nm, blue light may have a peak wavelength in a range of about 440 nm to 480 nm, and yellow light may have a peak wavelength in a range of about 570 nm to 610 nm. The peak wavelength may be a wavelength at which the intensity of light is maximum.

Referring to FIG. 5, a first transmission area TA1, a second transmission area TA2, and a third transmission area TA3 may be defined in the display area DA of the light transmitting portion 200. The first transmission area TA1, the second transmission area TA2, and the third transmission area TA3 may be areas through which the light generated in the first emission area EA1, the second emission area EA2, and the third emission area EA3 of the light emitting portion 100 passes. A light blocking area BA may be positioned in the periphery of the first transmission area TA1, the second transmission area TA2, and the third transmission area TA3 in the display area DA of the light transmitting portion 200. In one embodiment, the light blocking area BA may surround the first transmission area TA1, the second transmission area TA2, and the third transmission area TA3 in a plan view, but is not limited thereto. For example, the light blocking area BA may be positioned in the non-display area NDA as well as the display area DA of the light transmitting portion 200.

The first transmission area TA1 may correspond to and overlap the first emission area EA1, the second transmission area TA2 may correspond to and overlap the second emission area EA2, and the third transmission area TA3 may correspond to and overlap the third emission area EA3. In one embodiment, the first transmission area TA1 and the first emission area EA1 may have substantially the same area and completely overlap each other, the second transmission area TA2 and the second emission area EA2 may have substantially the same area and completely overlap each other, and the third transmission area TA3 and the third emission area EA3 may have substantially the same area and completely overlap each other in a plan view, but the disclosure is not limited thereto. For example, the first transmission area TA1 and the first emission area EA1 may have different areas, the second transmission area TA2 and the second emission area EA2 may have different areas, and the third transmission area TA3 and the third emission area EA3 may have different areas in a plan view. Hereinafter, for simplicity of description, description will be made focusing on an embodiment that the first transmission area TA1 and the first emission area EA1 have substantially the same area and completely overlap each other, the second transmission area TA2 and the second emission area EA2 have substantially the same area and completely overlap each other, and the third transmission area TA3 and the third emission area EA3 have substantially the same area and completely overlap each other in a plan view.

As described above, the light LE emitted from the light emitting portion 100 may pass through the filling portion 500, the light transmitting portion 200, and the color filter portion 300 and be provided to the outside of the display device 1. The light emitted from each pixel of the color filter portion 300 may be defined as the emission light. The emission light may include first emission light L1, second emission light L2, and third emission light L3. Light emitted from the first emission area EA1 to the outside of the display device 1 may be first emission light L1, light emitted from the second emission area EA2 to the outside of the display device 1 may be second emission light L2, and light emitted from the third emission area EA3 to the outside of the display device 1 may be third emission light L3. The first emission light L1 may be light of a third color, the second emission light L2 may be light of a second color, and the third emission light L3 may be light of a first color. In one embodiment, the light of the first color may be blue light, the light of the second color may be green light, and the light of the third color may be red light.

Hereinafter, the structure of the display device 1 will be described in detail.

Referring to FIG. 5, as described above, the display device 1 may include the light emitting portion 100, the light transmitting portion 200 disposed on the light emitting portion 100 facing the light emitting portion 100, the color filter portion 300, and the filling portion 500 interposed between the light emitting portion 100 and the light transmitting portion 200. Hereinafter, for simplicity of description, the light emitting portion 100, the color filter portion 300, the light transmitting portion 200, and the filling portion 500 will be described in order.

The light emitting portion 100 may be a structure in which a first substrate 110, a buffer layer 120, a lower metal layer BML, a first insulating layer 130, a semiconductor layer ACT, a gate electrode GE, a gate insulating layer 140, a second insulating layer 150, a source/drain electrode, a third insulating layer 160, a light emitting element, the pixel defining film 170, a first capping layer CPL1, and a thin film encapsulation layer are sequentially stacked on a side of the third direction DR3.

The first substrate 110 of the light emitting portion 100 may serve as a base of the light emitting portion 100. The first substrate 110 may be made of a light transmitting material. The first substrate 110 may be a glass substrate or a plastic substrate. In case that the first substrate 110 is a plastic substrate, the first substrate 110 may have flexibility. In one embodiment, in case that the first substrate 110 is a plastic substrate, the first substrate 110 may include polyimide, but is not limited thereto.

The buffer layer 120 of the light emitting portion 100 may be disposed on the first substrate 110. The buffer layer 120 may serve to block foreign matter or moisture penetrating through the first substrate 110 to the element disposed on the buffer layer 120.

In one embodiment, the buffer layer 120 may include an inorganic material such as SiOₓ, SiN_{y}, or SiOₓN_{y}, and may be formed as a single layer or multilayer, but is not limited thereto.

The lower metal layer BML of the light emitting portion 100 may be disposed on the buffer layer 120. The lower metal layer BML may block external light or light emitted from a light emitting element to be described below from being introduced into the semiconductor layer ACT. Accordingly, it may be possible to prevent or reduce the occurrence of leakage current due to light in the thin film transistor to be described below.

The lower metal layer BML may be made of a material that blocks light and may have conductivity. In one embodiment, the lower metal layer BML may include a metal such as silver (Ag), nickel (Ni), gold (Au), platinum (Pt), aluminum (Al), copper (Cu), molybdenum (Mo), titanium (Ti), neodymium (Nd), or an alloy thereof. In one embodiment, the lower metal layer BML may have a single-layer or multilayer structure. For example, in case that the lower metal layer BML has a multilayer structure, the lower metal layer BML may have a stacked structure of titanium (Ti)/copper (Cu)/indium tin oxide (ITO), or a stacked structure of titanium (Ti)/copper (Cu)/aluminum oxide (Al₂O₃), but is not limited thereto.

In one embodiment, the lower metal layer BML may be provided in plural to correspond to each semiconductor layer ACT and may overlap the semiconductor layer ACT in a plan view. In one embodiment, the width of the lower metal layer BML may be greater than the width of the semiconductor layer ACT in a horizontal direction.

In one embodiment, the lower metal layer BML may be a part of a data line, a power supply line, a wire that electrically connects the thin film transistor (not illustrated in the drawing) and the thin film transistor (GE, ACT, DE, and SE in FIG. 5) illustrated in the drawing to each other, and the like. In one embodiment, the lower metal layer BML may be made of a material having a lower resistance than the resistance of the source electrode SE and the drain electrode DE.

The first insulating layer 130 of the light emitting portion 100 may be disposed on the lower metal layer BML. The first insulating layer 130 may serve to electrically insulate the lower metal layer BML from the semiconductor layer ACT. The first insulating layer 130 may cover the lower metal layer BML.

In one embodiment, the first insulating layer 130 may include an inorganic material such as SiOₓ, SiN_{y}, SiOₓN_{y}, Al₂O₃, TiO₂, Ta₂O, HfO₂, or ZrO₂, but is not limited thereto.

The semiconductor layer ACT of the light emitting portion 100 may be disposed on the first insulating layer 130. The semiconductor layer ACT may be disposed to correspond to each of the first emission area EA1, the second emission area EA2, and the third emission area EA3 in the display area DA of the light emitting portion 100. Further, the semiconductor layer ACT may overlap the lower metal layer BML in a plan view, thereby suppressing generation of a photocurrent in the semiconductor layer ACT.

The semiconductor layer ACT may include an oxide semiconductor. In one embodiment, the semiconductor layer ACT may be formed of a zinc (Zn) oxide-based material, e.g., Zn oxide, In—Zn oxide, or Ga—In—Zn oxide, and may be an In—Ga—Zn—O (IGZO) semiconductor containing a metal such as indium (In) or gallium (Ga), but is not limited thereto. For example, the semiconductor layer ACT may include amorphous silicon or polysilicon.

The gate electrode GE of the light emitting portion 100 may be disposed on the semiconductor layer ACT. The gate electrode GE may overlap the semiconductor layer ACT in the display area DA in a plan view. In one embodiment, the width of the gate electrode GE may be less than the width of the semiconductor layer ACT in a horizontal direction, but is not limited thereto.

In one embodiment, the gate electrode GE may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) in consideration of adhesion with an adjacent layer, surface flatness of a stacked layer, processability, and the like, and may be formed into a single layer or multiple layers, but is not limited thereto.

The gate insulating layer 140 of the light emitting portion 100 may be disposed between the semiconductor layer ACT and the gate electrode GE. The gate insulating layer 140 may insulate the semiconductor layer ACT from the gate electrode GE. In one embodiment, the gate insulating layer 140 may be formed in a partially patterned shape on a side of the first substrate 110 in the third direction DR3, and the width of the gate insulating layer 140 may be less than the width of the semiconductor layer ACT and be greater than the width of the gate electrode GE in a horizontal direction, but the disclosure is not limited thereto.

In one embodiment, the gate insulating layer 140 may include an inorganic material. For example, the gate insulating layer 140 may include an inorganic material exemplified in the description of the first insulating layer 130.

The second insulating layer 150 of the light emitting portion 100 may be disposed on the gate insulating layer 140 and cover the semiconductor layer ACT and the gate electrode GE. In one embodiment, the second insulating layer 150 may function as a planarization layer providing a flat surface.

The second insulating layer 150 may include an organic material. In one embodiment, the second insulating layer 150 may include at least one of an acrylic resin, an epoxy resin, an imide resin, an ester resin, and the like, or may include a photosensitive organic material, but is not limited thereto.

The source electrode SE and the drain electrode DE of the light emitting portion 100 may be spaced apart from each other and disposed on the second insulating layer 150. The source electrode SE and the drain electrode DE may be connected to the semiconductor layer ACT through contact holes penetrating the second insulating layer 150, respectively. In one embodiment, the source electrode SE may penetrate the first insulating layer 130 as well as the second insulating layer 150 and may be connected to the lower metal layer BML. In case that the lower metal layer BML is a part of a wire that transmits a signal, a voltage, and the like, the source electrode SE may be connected and electrically coupled to the lower metal layer BML to receive a transmitted voltage and the like provided to the wire. In another embodiment, in case that the lower metal layer BML is a floating pattern rather than a separate wire, a voltage and the like provided to the source electrode SE may be transmitted to the lower metal layer BML and the like.

The source electrode SE and the drain electrode DE may each include aluminum (Al), copper (Cu), titanium (Ti), and the like, and may be formed as a multilayer or a single layer. In one embodiment, the source electrode SE and the drain electrode DE may have a multilayer structure of Ti/Al/Ti, but are not limited thereto.

The semiconductor layer ACT, the gate electrode GE, the source electrode SE, and the drain electrode DE described above may form a thin film transistor that is a switching element. In one embodiment, the thin film transistor may be located in each of the first emission area EA1, the second emission area EA2, and the third emission area EA3. In one embodiment, a part of the thin film transistor may be located in the non-emission area NEA.

The third insulating layer 160 of the light emitting portion 100 may be disposed on the second insulating layer 150 and cover the thin film transistor. In one embodiment, the third insulating layer 160 may be a planarization layer.

The third insulating layer 160 may be made of an organic material. In one embodiment, the third insulating layer 160 may include at least one of an acrylic resin, an epoxy resin, an imide resin, an ester resin, and the like, or may include a photosensitive organic material, but is not limited thereto.

Multiple anode electrodes ANO may be located on the third insulating layer 160 in the display area DA of the light emitting portion 100. The anode electrodes ANO may be spaced apart from each other in a horizontal direction.

The anode electrodes ANO may overlap the first emission area EA1, the second emission area EA2, and the third emission area EA3 in a plan view, respectively, and may extend at least partially to the non-emission area NEA. The anode electrodes ANO may be connected to the drain electrode DE of the thin film transistor.

In one embodiment, the anode electrode ANO may be reflective electrodes, in which case the anode electrode ANO may be a metal layer containing a metal such as Ag, Mg, Al, Pt, Pd, Au, Ni, Nd, Ir, or Cr. In another embodiment, the anode electrode ANO may further include a metal oxide layer stacked on the metal layer. In an embodiment, the anode electrode ANO may have a multilayer structure, for example, a two-layer structure such as ITO/Ag, Ag/ITO, ITO/Mg, and ITO/MgF, or a three-layer structure of ITO/Ag/ITO.

The pixel defining film 170 of the light emitting portion 100 may be disposed on the anode electrode ANO. The pixel defining film 170 may define the first emission area EA1, the second emission area EA2, and the third emission area EA3 as openings exposing the anode electrodes ANO, respectively. The pixel defining film 170 may overlap edges of the anode electrodes ANO in a plan view.

The pixel defining film 170 may overlap the light blocking area BA of the color filter layer 320 to be described below in the third direction DR3. The pixel defining film 170 may overlap the bank pattern BK, which will be described below, in the third direction DR3.

In one embodiment, the pixel defining film 170 may include an organic insulating material such as an acrylic resin, an epoxy resin, a phenolic resin, a polyamide resin, a polyimide resin, an unsaturated polyester resin, a polyphenylene ether resin, a polyphenylenesulfide resin, and benzocyclobutene (BCB), but is not limited thereto.

A light emitting layer OL of the light emitting portion 100 may be disposed on the anode electrode ANO. In one embodiment, the light emitting layer OL may have a shape of a continuous film formed over the emission areas EA1, EA2, and EA3 and the non-emission area NEA. In one embodiment, the light emitting layer OL may be located only in the display area DA, but is not limited thereto. For example, a part of the light emitting layer OL may be further disposed in the non-display area NDA. A more detailed description of the light emitting layer OL will be given below.

The cathode electrode CE of the light emitting portion 100 may be disposed on the light emitting layer OL. In one embodiment, the cathode electrode CE may be disposed on the light emitting layer OL and have a continuous film shape formed over the emission areas EA1, EA2, and EA3 and the non-emission area NEA. In other words, the cathode electrode CE may completely cover the light emitting layer OL.

The cathode electrode CE may have a semi-transmissive or transmissive property. In case that the cathode electrode CE has a thickness of tens to hundreds of angstroms, the cathode electrode CE may have a semi-transmissive property. In one embodiment, in case that the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or mixture thereof, such as a mixture of Ag and Mg. The cathode electrode CE may include a transparent conductive oxide to have a transmissive property. In one embodiment, in case that the cathode electrode CE has the transmissive property, the cathode electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or the like.

The anode electrode ANO, the light emitting layer OL, and the cathode electrode CE may form a light emitting element. For example, the anode electrode ANO, the light emitting layer OL, and the cathode electrode CE in the first emission area EA1 may form a first light emitting element, the anode electrode ANO, the light emitting layer OL, and the cathode electrode CE in the second emission area EA2 may form a second light emitting element, and the anode electrode ANO, the light emitting layer OL, and the cathode electrode CE in the third emission area EA3 may form a third light emitting element. Each of the first light emitting element, the second light emitting element, and the third light emitting element may emit emission light LE.

According to one embodiment, each light emitting element may be a tandem type light emitting element and may emit mixed light in which two or more component lights are mixed. Each light emitting element may include multiple stacks that emit light of a color. The light emitting layer OL of the light emitting element may include a first light emitting layer that emits the light of the first color, and a second light emitting layer that emits the light of the second color and overlaps the first light emitting layer. The disclosure is not limited thereto, and the light emitting layer OL of the light emitting element may include the first light emitting layer that emits the light of the first color, the second light emitting layer that emits the light of the second color, and the third light emitting layer that emits the light of the third color, to emit white light. The first to third light emitting layers may overlap each other in the third direction DR3.

In one embodiment, the emission light LE emitted from the light emitting element may be mixed light, and may be a mixture of first component light LE1 and second component light LE2. The first component light LE1 may be the light of the first color, and the second component light LE2 may be the light of the second color or the light of the third color. The peak wavelengths of the first to third colors may be different from each other.

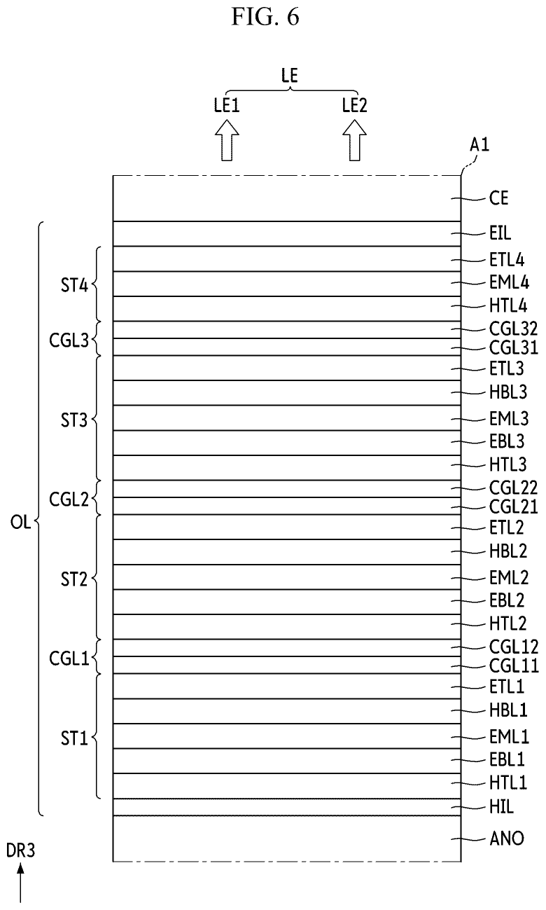

FIG. 6 is an enlarged view of area A1 in FIG. 5, and schematically illustrates the light emitting layer OL of the light emitting element.

Referring to FIG. 6, the emission light LE ultimately emitted from the light emitting layer OL may be mixed light in which the first component light LE1 and the second component light LE2 are mixed. In one embodiment, the first color of the first component light LE1 may be blue, and the second color of the second component light LE2 may be green. The peak wavelength of the first component light LE1 may be in a range of about 440 nm to about 480 nm, and the peak wavelength of the second component light LE2 may be in a range of about 510 nm to about 550 nm. In another embodiment, the first color of the first component light LE1 may be blue, and the third color of the second component light LE2 may be red. The peak wavelength of the first component light LE1 may be in a range of about 440 nm to about 480 nm, and the peak wavelength of the second component light LE2 may be in a range of about 610 nm to about 650 nm.

In one embodiment, the light emitting layer OL may have a structure, e.g., a tandem structure, in which multiple light emitting layers overlap each other in the third direction DR3. The tandem structure may include multiple stacks including a hole transport layer, a light emitting layer, and an electron transport layer, and the stacks may be stacked in the thickness direction or the length direction. The light emitting layer OL may include a hole injection layer HIL disposed on the anode ANO, multiple stacks ST1, ST2, ST3, and ST4 disposed on the hole injection layer HIL, an electron injection layer EIL disposed on the stacks ST1, ST2, ST3, and ST4, and charge generation layers CGL1, CGL2, and CGL3 each disposed between adjacent stacks ST1, ST2, ST3, and ST4.

The hole injection layer HIL may be a layer that serves to readily perform the injection of holes from the anode electrode ANO into the stacks ST1, ST2, ST3, and ST4, may include a hole injection material that has the ability to transport holes from the anode electrode at a low voltage, and may have an excellent hole injection effect. Examples of hole injection materials may include metal porphyrine, oligothiophene, an arylamine-based organic material, a hexanitrilehexaazatriphenylene-based organic material, a quinacridone-based organic material, a perylene-based organic material, a anthraquinone-based conductive polymer, a polyaniline-based conductive polymer, a polythiophene-based conductive polymer, a diamine compound including aryl or heteroaryl group, copper phthalocyanine (CuPc), poly(3,4)-ethylenedioxythiophene (PEDOT), polyaniline (PANI), N,N-dinaphthyl-N,N′-diphenyl benzidine (NPD), or the like, but the disclosure is not limited thereto.

Multiple stacks may be disposed on the hole injection layer HIL. For example, the light emitting layer OL may include four or more stacks, and two or more component lights may be emitted from the light emitting layer OL. The light emitting layer OL may include multiple stacks that emit the first component light LE1.

In one embodiment, the light emitting layer OL may include a first stack ST1 including a first light emitting layer EML1, a second stack ST2 including a second light emitting layer EML2 and located above the first stack ST1, a third stack ST3 including a third light emitting layer EML3 and located above the second stack ST2, and a fourth stack ST4 including a fourth light emitting layer EML4 and located above the third stack ST3. The light emitting layer OL may further include a first charge generation layer CGL1 located between the first stack ST1 and the second stack ST2, a second charge generation layer CGL2 located between the second stack ST2 and the third stack ST3, and a third charge generation layer CGL3 located between the third stack ST3 and the fourth stack ST4.

The first to fourth stacks ST1, ST2, ST3, and ST4 may overlap each other in the third direction DR3. The first to fourth light emitting layers EML1, EML2, EML3, and EML4 may overlap each other in the third direction DR3. The first to fourth stacks ST1, ST2, ST3, and ST4 may be sequentially disposed on the hole injection layer HIL in the thickness direction.

Some of the first to fourth stacks ST1, ST2, ST3, and ST4 may emit the first component light LE1, and others may emit the second component light LE2. In one embodiment, three of the stacks ST1, ST2, ST3, and ST4 may emit the first component light LE1, and another one of the stacks ST1, ST2, ST3, and ST4 may emit the second component light LE2. However, the disclosure is not limited thereto, and two of the stacks ST1, ST2, ST3, and ST4 may emit the first component light LE1, and the other two of the stacks ST1, ST2, ST3, and ST4 may emit the second component light LE2.

In one embodiment, the first light emitting layer EML1, the second light emitting layer EML2, and the third light emitting layer EML3 may emit the first component light LE1, for example, blue light. The fourth light emitting layer EML4 may emit the second component light LE2, for example, green light. However, the stacking order of the stack according to the color emitted is not limited thereto.

In one embodiment, each of the first light emitting layer EML1, the second light emitting layer EML2, and the third light emitting layer EML3 may include a host and a blue dopant. Although the host is not particularly limited as long as it is a commonly used material, a condensed ring derivative such as anthracene or pyrene, a metal chelated oxinoid compound such as tris(8-quinolinolato)aluminum, a bistyryl derivative such as a bistyryl anthracene derivative or a distyrylbenzene derivative, a tetraphenylbutadiene derivative, a coumarin derivative, an oxadiazole derivative, a perinone derivative, a cyclopentadiene derivative, a pyrrolopyridine derivative, a pyrrolopyrrole derivative, a thiadiazolopyridine derivative, an oxadiazole derivative, in polymer series, a polyphenylenevinylene derivative, a polyparaphenylene derivative, and a polythiophene derivative may be used, and a substituent such as aryl, heteroaryl, arylvinyl, amino, and cyano may be introduced into the derivative. For example, tris(8-hydroxyquinolinato)aluminium (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), or the like may be used.

The blue dopant is not particularly limited as long as it is a commonly used material, but may include, for example, a fluorescent material such as spiro-DPVBi, spiro-6P, distyryl-benzene (DSB), distyryl-arylene (DSA), a polyfluorene (PFO)-based polymer, a poly(p-phenylene vinylene) (PPV)-based polymer, and a DABNA-based boron polycyclic compound. In another embodiment, a phosphorescent material containing an organometallic complex such as (4,6-F₂ppy)₂Ir(pic) may be included. A substituent such as aryl, heteroaryl, arylvinyl, amino, and cyano may be introduced into the compound used in the blue dopant.

In one embodiment, the fourth light emitting layer EML4 may include a green host and a green dopant. As the green host, a general green host material or the above-described host materials may be used. A green dopant material is not particularly limited as long as it is a commonly used material, but may include a coumarin derivative, a phthalimide derivative, a naphthalimide derivative, a perrinone derivative, an acridone derivative, a quinacridone derivative, a pyrrolopyrrole derivative, a cyclopentadiene derivative, a naphthacene derivative such as rubrene, or the like, and a substituent such as aryl, heteroaryl, arylvinyl, amino, and cyano may be introduced into the derivative compound. Examples may include a fluorescent material containing tris(8-hydroxyquinolinato)aluminium (III) (Alq₃), or a phosphorescent material such as fac tris(2-phenylpyridine)iridium (Ir(ppy)₃), bis(2-phenylpyridine)(acetylacetonate)iridium (III) (Ir(ppy)₂(acac)), and tris[2-(p-tolyl)pyridine]iridium (III) (Ir(mpyp)₃).

The stacks ST1, ST2, ST3, and ST4 may include hole transport layers HTL1, HTL2, HTL3, and HTL4, respectively. The hole transport layer HTL1, HTL2, HTL3, HTL4 may be located above the anode electrode ANO or the charge generation layer CGL1, CGL2, CGL3. The hole transport layers HTL1, HTL2, HTL3, and HTL4 may serve to facilitate the transport of holes and may include a hole transport material. The hole transport material may include a carbazole-based derivative such as N-phenylcarbazole and polyvinylcarbazole, a fluorene-based derivative, a triphenylamine-based derivative such as N,N′-bis(3-methylphenyl)-N,N′-diphenyl)-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-Cyclohexylidene bis[N,N-bis(4-methylphenyl)benzenamine] (TAPC), or the like, but the disclosure is not limited thereto.

The stacks ST1, ST2, ST3, and ST4 may include the above-described light emitting layers EML1, EML2, EML3, and EML4 above the hole transport layers HTL1, HTL2, HTL3, and HTL4, respectively.

The stacks ST1, ST2, ST3, and ST4 may include electron transport layers ETL1, ETL2, ETL3, and ETL4 above the light emitting layers EML1, EML2, EML3, and EML4, respectively. In one embodiment, the electron transport layers ETL1, ETL2, ETL3, and ETL4 may include an electron transport material such as tris(8-hydroxyquinolinato)aluminum (Alq₃), 1,3,5-tri (1-phenyl-1H-benzo[d]imidazol-2-yl)phenyl (TPBi), 2,9-dimethyl-4,7-diphenyl-1,10-phenanthroline (BCP), (4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl)anthracene (ADN), and a mixture thereof, but are not limited thereto.

The stack emitting blue light may further include an electron block layer and a hole block layer. In one embodiment, the first stack ST1, the second stack ST2, and the third stack ST3 may include electron block layers EBL1, EBL2, and EBL3 and hole block layers HBL1, HBL2, and HBL3.

The electron block layers EBL1, EBL2, and EBL3 may be disposed between the light emitting layers EML1, EML2, and EML3 and the hole transport layers HTL1, HTL2, and HTL3. The electron block layers EBL1, EBL2, and EBL3 may prevent electrons passing from the light emitting layers EML, EML2, and EML3 to the hole transport layers HTL1, HTL2, and HTL3. The electron block layers EBL1, EBL2, and EBL3 may include the above-described hole transport material, or the above-described hole transport material and a metal (or a metal compound). In one embodiment, the hole transport layers HTL1, HTL2, and HTL3 and the electron block layers EBL1, EBL2, and EBL3 described above may be constituted with a single layer in which the respective materials are blended.

The hole block layers HBL1, HBL2, and HBL3 may be disposed between the light emitting layers EML1, EML2, and EML3 and the electron transport layers ETL1, ETL2, and ETL3. The hole block layers HBL1, HBL2, and HBL3 may prevent holes that have passed through the light emitting layers EML1, EML2, and EML3 from crossing over to the electron transport layers ETL1, ETL2, and ETL3. The hole block layers HBL1, HBL2, and HBL3 may include the above-described electron transport material, or the above-described electron transport material and a metal (or a metal compound). In one embodiment, the electron transport layers ETL1, ETL2, and ETL3 and the hole block layers HBL1, HBL2, and HBL3 described above may be formed of a single layer in which the respective materials are blended.

The electron injection layer EIL may be disposed between the fourth stack ST4 and the cathode electrode CE and may serve to readily perform the injection of electrons from the cathode electrode CE to the stacks ST1, ST2, ST3, and ST4. The electron injection material may be a compound that can transport electrons and has an excellent electron injection effect. For example, the electron injection layer EIL may include tris(8-hydroxyquinolinato)aluminum (Alq₃), PBD, TAZ, spiro-PBD, BAlq or SAlq, but the disclosure is not limited thereto. For example, the electron injection layer EIL may include a metal halide compound, and may include at least one of MgF₂, LiF, NaF, KF, RbF, CsF, FrF, LiI, NaI, KI, RbI, CsI, FrI and CaF₂, but the disclosure is not limited thereto. For example, the electron injection layer EIL may include a lanthanum-based material such as Yb, Sm, Eu, or the like. In another embodiment, the electron injection layer EIL may include a metal halide material and a lanthanum-based material, such as RbI:Yb, KI:Yb, or the like. In case that the electron injection layer EIL includes both a metal halide material and a lanthanum-based material, the electron injection layer EIL may be formed by co-deposition of a metal halide material and a lanthanum-based material.

The charge generation layers CGL1, CGL2, and CGL3 may be disposed between adjacent stacks ST1, ST2, ST3, and ST4. The charge generation layers CGL1, CGL2, and CGL3 may inject charges into each of the stacks ST1, ST2, ST3, and ST4 and may adjust the charge balance between two adjacent stacks. The first charge generation layer CGL1 may be disposed between the first stack ST1 and the second stack ST2, the second charge generation layer CGL2 may be disposed between the second stack ST2 and the third stack ST3. and the third charge generation layer CGL3 may be disposed between the third stack ST3 and the fourth stack ST4. The charge generation layers CGL1, CGL2, and CGL3 may include n-type charge generation layers CGL11, CGL21, and CGL31 and p-type charge generation layers CGL12, CGL22, and CGL32. The n-type charge generation layers CGL11, CGL21, and CGL31 may be disposed on the electron transport layers ETL1, ETL2, ETL3, and ETL4, and the p-type charge generation layers CGL12, CGL22, and CGL32 may be disposed between the n-type charge generation layers CGL11, CGL21, and CGL31 and the hole transport layers HTL2, HTL3, and HTL4.

The charge generation layers CGL1, CGL2, and CGL3 may have a structure in which the n-type charge generation layers CGL11, CGL21, and CGL31 and the p-type charge generation layers CGL12, CGL22, and CGL32 are bonded to each other. The n-type charge generating layers CGL11, CGL21, and CGL31 may be disposed closer to the anode electrode ANO between the anode electrode ANO and the cathode electrode CE. The p-type charge generation layers CGL12, CGL22, and CGL32 may be disposed closer to the cathode electrode CE between the anode electrode ANO and the cathode electrode CE.

In one embodiment, some of the stacks may emit component light of a first color, some others may emit component light of a second color, and the others may emit component light of a third color. The light emitting layer OL may include the first light emitting layer that emits the light of the first color, the second light emitting layer that emits the light of the second color, and the third light emitting layer that emits the light of the third color and may emit white light that is mixed light of the first to third colors.

Referring to FIG. 5, a first capping layer CPL1 may be disposed on the cathode electrode CE. The first capping layer CPL1 may serve to improve viewing angle and increase external luminous efficiency. The first capping layer CPL1 may be commonly disposed in the first emission area EA1, the second emission area EA2, the third emission area EA3, and the non-emission area NEA. The first capping layer CPL1 may completely cover the cathode electrode CE.

The first capping layer CPL1 may include at least one of an inorganic material having a light transmissive property or an organic material. In other words, the first capping layer CPL1 may be formed of an inorganic layer, formed of an organic layer, or formed of an organic layer including inorganic particles. In one embodiment, the first capping layer CPL1 may include a triamine derivative, a carbazole biphenyl derivative, an arylenediamine derivative, an aluminum chelate compound (Alq₃), or the like, but is not limited thereto.

A thin film encapsulation layer TFE of the light emitting portion 100 may be disposed on the first capping layer CPL1. The thin film encapsulation layer TFE may serve to protect components positioned under the thin film encapsulation layer TFE from external foreign matter such as moisture. The thin film encapsulation layer may be commonly disposed in the first emission area EA1, the second emission area EA2, the third emission area EA3, and the non-emission area NEA. The thin film encapsulation layer may completely cover the first capping layer CPL1.

The thin film encapsulation layer TFE may include a lower inorganic encapsulation layer TFEa, an organic encapsulation layer TFEb, and an upper inorganic encapsulation layer TFEc sequentially stacked on the first capping layer CPL1.

The lower inorganic encapsulation layer TFEa may completely cover the first capping layer CPL1 in the display area DA and cover the first light emitting element, the second light emitting element, and the third light emitting element. The organic encapsulation layer TFEb may be disposed on the lower inorganic encapsulation layer TFEa and completely cover the lower inorganic encapsulation layer TFEa. The upper inorganic encapsulation layer TFEc may be disposed on the organic encapsulation layer TFEb and completely cover the organic encapsulation layer TFEb.

In one embodiment, each of the lower inorganic encapsulation layer TFEa and the upper inorganic encapsulation layer TFEc may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiOₓN_{y}), lithium fluoride, or the like, but is not limited thereto.

In one embodiment, the organic encapsulation layer TFEb may be formed of an acrylic resin, a methacrylic resin, polyisoprene, a vinyl resin, an epoxy resin, a urethane resin, a cellulose resin, a perylene resin or the like, but is not limited thereto.

Hereinafter, the light transmitting portion 200 and the color filter portion 300 will be described with reference to FIG. 5.

A structure may be provided in which the light transmitting portion 200 is stacked on the other side of the color filter portion 300 including a second substrate 310 in the third direction DR3. The color filter portion 300 may have a structure in which the second substrate 310, the color filter layer 320, and a second capping layer CPL2 are sequentially stacked on the other side in the third direction DR3, and the light transmitting portion 200 may include the light transmitting member WCL1, WCL2, and TPL and the bank pattern BK disposed on the second capping layer CPL2, and a third capping layer CPL3 disposed on the light transmitting member WCL1, WCL2, and TPL and the bank pattern BK.

The second substrate 310 of the color filter portion 300 may serve as a base of the color filter portion 300. The second substrate 310 may be made of a light transmitting material. The second substrate 310 may be a glass substrate or a plastic substrate. In case that the second substrate 310 is a plastic substrate, the second substrate 310 may have flexibility. In one embodiment, in case that the second substrate 310 is a plastic substrate, the second substrate 310 may include polyimide, but is not limited thereto. As described above, since the light emitting portion 100 and the color filter portion 300 face each other in the third direction DR3, the first substrate 110 of the light emitting portion 100 and the second substrate 310 of the color filter portion 300 may face each other in the third direction DR3.

The color filter layer 320 of the color filter portion 300 may be disposed on the other side of the second substrate 310 in the third direction DR3, for example, between the second substrate 310 and the light emitting portion 100. The color filter layer 320 may include a filtering pattern area and a light blocking pattern portion BM. The light blocking pattern portion BM may surround the filtering pattern area in a plan view. The filtering pattern of the color filter layer 320 may define transmission areas TA1, TA2, and TA3 of the light transmitting portion 200, and the light blocking pattern portion BM may define the light blocking area BA of the light transmitting portion 200.

As illustrated in FIG. 5, the color filter layer 320 may include a first color filter 321, a second color filter 322, and a third color filter 323. The first color filter 321 may absorb all of the second emission light L2 and the third emission light L3 except for the first emission light L1, the second color filter 322 may absorb all of the first emission light L1 and the third emission light L3 except for the second emission light L2, and the third color filter 323 may absorb all of the first emission light L1 and the second emission light L2 except for the third emission light L3. In other words, the first color filter 321 may transmit the first emission light L1, the second color filter 322 may transmit the second emission light L2, and the third color filter 323 may transmit the third emission light L3. In one embodiment, the first emission light L1 may be the third color, e.g., red, the second emission light L2 may be the second color, e.g., green, and the third emission light L3 may be the first color, e.g., blue.

In one embodiment, the first color filter 321 may be a red color filter and may include a red colorant. In the disclosure, the colorant may include both a dye and a pigment. The first color filter 321 may include a base resin, and the red colorant may be dispersed in the base resin. In one embodiment, the second color filter 322 may be a green color filter and may include a green colorant. The second color filter 322 may include a base resin and the green colorant may be dispersed in the base resin. In one embodiment, the third color filter 323 may be a blue color filter and may include a blue colorant. The third color filter 323 may include a base resin, and the blue colorant may be dispersed in the base resin.

The first color filter 321 may include a first filtering pattern area 321a and a first blocking pattern area 321b surrounding the first filtering pattern area 321a in a plan view, the second color filter 322 may include a second filtering pattern area 322a and a second blocking pattern area 322b surrounding the second filtering pattern area 322a in a plan view, and the third color filter 323 may include a third filtering pattern area 323a and a third blocking pattern area 323b surrounding the third filtering pattern area 323a in a plan view. For example, the first filtering pattern area 321a of the first color filter 321 may overlap the first transmission area TA1, and the first blocking pattern area 321b of the first color filter 321 may surround the first filtering pattern area 321a overlapping the first transmission area TA1, however may not overlap a second transmission area TA2 and a third transmission area TA3, and may overlap the light blocking area BA in a plan view. The second filtering pattern area 322a of the second color filter 322 may overlap the second transmission area TA2, and the second blocking pattern area 322b of the second color filter 322 may surround the second filtering pattern area 322a overlapping the second transmission area TA2, however may not overlap the first transmission area TA1 and the third transmission area TA3, and may overlap the light blocking area BA in a plan view. The third filtering pattern area 323a of the third color filter 323 may overlap the third transmission area TA3, and the third blocking pattern area 323b of the third color filter 323 may surround the third filtering pattern area 323a overlapping the third transmission area TA3, however may not overlap the first transmission area TA1 and the second transmission area TA2, and may overlap the light blocking area BA in a plan view. In other words, the filtering pattern area of the color filter layer 320 may include the first filtering pattern area 321a of the first color filter 321, the second filtering pattern area 322a of the second color filter 322, and the third filtering pattern area 323a of the third color filter 323, and the light blocking pattern portion BM may have a structure in which the first blocking pattern area 321b of the first color filter 321, the second blocking pattern area 322b of the second color filter 322, and the third blocking pattern area 323b of the third color filter 323 are stacked one another.

In one embodiment, the light blocking pattern portion BM may have a structure in which the first blocking pattern area 321b, the third blocking pattern area 323b, and the second blocking pattern area 322b are sequentially stacked on the other side of the third direction DR3, but the disclosure is not limited thereto. For example, the light blocking pattern portion BM may not be constituted with the color filters 321, 322, and 323 described above, but may be formed as a separate organic light blocking material through coating and exposure processes of the organic light blocking material, and the like. Hereinafter, for simplicity of description, description will be made based on an embodiment that the light blocking pattern has a structure in which the first blocking pattern area 321b, the third blocking pattern area 323b, and the second blocking pattern area 322b are sequentially stacked on the other side of the third direction DR3. The light blocking pattern portion BM may absorb all of the first emission light L1, the second emission light L2, and the third emission light L3 through the above-described configuration.

A low refractive layer LR may be disposed on the color filter layer 320. The low refractive layer LR may have a refractive index lower than a light transmitting layer TPL, a first wavelength conversion layer WCL1, and a second wavelength conversion layer WCL2, which will be described below, and thus may serve to recycle light by inducing total reflection of light traveling from the light transmitting layer TPL, the first wavelength conversion layer WCL1, and the second wavelength conversion layer WCL2 to the low refractive layer LR.

Further, the low refractive layer LR may serve to flatten by compensating for stepped portions generated by the blocking pattern areas 321b, 322b, and 323b of the color filter layer 320. Accordingly, the second capping layer CPL2 disposed on the low refractive layer LR may be formed flat. The thickness of the low refractive layer LR in the light blocking area BA and the thickness in the transmission areas TA1, TA2, and TA3 may be different from each other, and the thickness of the low refractive layer LR in the light blocking area BA may be smaller than the thickness in the transmission areas TA1, TA2, and TA3.

The second capping layer CPL2 of the light transmitting portion 200 may be disposed on a surface of the low refractive layer LR and cover the low refractive layer LR. The second capping layer CPL2 may prevent impurities such as moisture or air from the outside from permeating into the low refractive layer LR or the color filter layer 320 and damaging or contaminating the filtering pattern area and the light blocking pattern portion BM of the low refractive layer LR and the color filter layer 320. The second capping layer CPL2 may include an inorganic material. The second capping layer CPL2 may be formed as a single layer or multiple layers.

The refractive index of the second capping layer CPL2 may be greater than the refractive index of the low refractive layer LR, and total reflection may occur well in the low refractive layer LR, and light may be recycled.

Hereinafter, the light transmitting portion 200 will be described with reference to FIG. 5.

The bank pattern BK of the light transmitting portion 200 may be disposed on the second capping layer CPL2 as illustrated in FIG. 5 and form a space accommodating a light transmitting member to be described below. Multiple spaces accommodating the light transmitting member may be configured, and may be spaced apart from each other. For example, the bank pattern BK may serve to partition a space in which a light transmitting member is disposed. The bank pattern BK may be in direct contact with the second capping layer CPL2. The bank pattern BK may surround the light transmitting member in a plan view. The bank pattern BK may overlap the non-emission area NEA of the light emitting portion 100 and the light blocking area BA of the light transmitting portion 200 in a plan view. The bank pattern BK may not overlap the emission areas EA1, EA2, and EA3 of the light emitting portion 100 and the transmission areas TA1, TA2, and TA3 of the light transmitting portion 300 in a plan view.

In one embodiment, the bank pattern BK may include an organic material having photocurability or an organic material having photocurability and including a light blocking material, but is not limited thereto.

The light transmitting member of the light transmitting portion 200 may be disposed on the second capping layer CPL2 exposed by the separation space of the bank pattern BK. The light transmitting member may include the first wavelength conversion layer WCL1 in the first transmission area TA1, the second wavelength conversion layer WCL2 in the second transmission area TA2, and the light transmitting layer TPL in the third transmission area TA3. The light transmitting layer TPL, the first wavelength conversion layer WCL1 and the second wavelength conversion layer WCL2 may be referred to as a wavelength conversion layer or a wavelength conversion material layer.

The first wavelength conversion layer WCL1 may be disposed in a space partitioned by the bank pattern BK, and may overlap the first emission area EA1 and the first transmission area TA1 in the third direction DR3. The first wavelength conversion layer WCL1 may be in direct contact with the second capping layer CPL2 and the bank pattern BK.

The first wavelength conversion layer WCL1 may be a wavelength conversion pattern that converts or shifts the peak wavelength of incident light into light of another peak wavelength to emit the light. For example, as described above, the emission light LE provided from the first light emitting element may be mixed light and may pass through the first wavelength conversion layer WCL1 and the first filtering pattern area 321a of the first color filter 321 and be converted into red light having a peak wavelength in a range of about 610 nm to about 650 nm to be emitted to the outside of the display device 1. In other words, the first emission light L1 passing through the first transmission area TA1 in the first emission area EA1 and emitted to the outside may be red light.

The first wavelength conversion layer WCL1 may include a base resin 330, a light scatterer 331 dispersedly disposed in the base resin 330, and a first wavelength shifter 332 dispersedly disposed in the base resin 330.

The base resin 330 may be made of an organic material having high light transmittance. In one embodiment, the base resin 330 may include an organic material such as an epoxy resin, an acrylic resin, a silicone resin, a cardo resin, or an imide resin, but is not limited thereto.

The light scatterer 331 may have a refractive index different from a refractive index of the base resin 330 and form an optical interface with the base resin 330. The light scatterer 331 may be a light scattering particle. The light scatterer 331 may scatter light in a random direction irrespective of the incident direction of incident light, without substantially converting the wavelength of the light passing through the first transmission area TA1.

The light scatterer 331 may include a material that scatters at least a part of transmitted light, and may include metal oxide particles or organic particles. In one embodiment, the light scatterer 331 may include titanium oxide (TiO₂), zirconium oxide (ZrO₂), aluminum oxide (Al₂O₃), indium oxide (In₂O₃), zinc oxide (ZnO), tin oxide (SnO₂), or the like as a metal oxide, or may include an acrylic resin, a urethane-based resin, or the like as the organic particles, but is not limited thereto.

The first wavelength shifter 332 may convert or shift the peak wavelength of incident light to another peak wavelength. The first wavelength shifter 332 may convert the emission light LE provided from the first light emitting element, into red light having a single peak wavelength in a range of 610 nm to about 650 nm and emit the light. The first wavelength shifter 332 may convert not only blue light but also green light into red light and emit the red light.

In one embodiment, the first wavelength shifter 332 may be a quantum dot, a quantum rod, or a fluorescent substance, but is not limited thereto. Hereinafter, for simplicity of description, the first wavelength shifter 332 will be described as a quantum dot according to an embodiment. The quantum dot may be a particulate material that emits light of a specific color in case that an electron transitions from a conduction band to a valence band. The quantum dot may be a semiconductor nanocrystal material. The quantum dot may have a specific band gap according to its composition and size. Thus, the quantum dot may absorb light and emit light having an intrinsic wavelength. Examples of semiconductor nanocrystal of quantum dots may include Group IV compound nanocrystal, Group II-VI compound nanocrystal, Group III-V compound nanocrystal, Group IV-VI compound nanocrystal, the like, or a combination thereof.

Group IV compounds, Group II-VI compounds, Group III-V compounds, and Group IV-VI compounds may be a binary compound, a tertiary compound, and a quaternary compound.

A binary compound, a tertiary compound or a quaternary compound may exist in particles at a uniform concentration, or may exist in a same particle divided into states where concentration distributions are partially different. Further, the particles may have a core/shell structure in which one quantum dot surrounds another quantum dot. An interface between the core and the shell may have a concentration gradient in which the concentration of elements present in the shell decreases toward the center.

In one embodiment, the quantum dot may have a core-shell structure including a core including the nanocrystal described above and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of elements present in the shell decreases toward the center. Examples of the shell of the quantum dot may include a metal oxide, a non-metal oxide, a semiconductor compound, and a combination thereof.

For example, a metal oxide or a non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, but the disclosure is not limited thereto.

For example, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but the disclosure is not limited thereto.

The light emitted from the first wavelength shifter 332 may have a full width of half maximum (FWHM) of the emission wavelength spectrum less than or equal to about 45 nm. For example, the light emitted from the first wavelength shifter 332 may have a full width of half maximum (FWHM) of the emission wavelength spectrum less than or equal to about 40 nm. For example, light emitted from the first wavelength shifter 332 may have a full width of half maximum (FWHM) of the emission wavelength spectrum less than or equal to about 30 nm. Thus, the purity and reproducibility of colors displayed by the display device 1 may be further improved. The light emitted from the first wavelength shifter 332 may be emitted in various directions regardless of the incident direction of incident light. Accordingly, the side visibility of the third color displayed in the first transmission area TA1 may be improved.

Some of the emission light LE provided from the first light emitting element may pass through the first wavelength conversion layer WCL1 and be emitted without being converted into red light by the first wavelength shifter 332. Among the emission light LE, a component whose wavelength is not converted by the first wavelength conversion layer WCL1 and which is incident on the first filtering pattern area 321a of the first color filter 321 may be blocked by the first filtering pattern area 321a. On the other hand, among the emission light LE, red light converted by the first wavelength conversion layer WCL1 may pass through the first filtering pattern area 321a and be emitted to the outside. For example, the first emission light L1 emitted to the outside of the display device 1 through the first transmission area TA1 may be red light. The first emission light L1 may include a component of light that is converted from blue light, which is the first component light LE1, to red light and passes through the first color filter 321, and a component in a wavelength band in which green light, which is the second component light LE2, passes through the first wavelength conversion layer WCL1 without change but is not blocked by the first color filter 321 to be leaked.

The second wavelength conversion layer WCL2 may be disposed in a space partitioned by the bank pattern BK, and may overlap the second emission area EA2 and the second transmission area TA2 in the third direction DR3. The second wavelength conversion layer WCL2 may be in direct contact with the second capping layer CPL2 and the bank pattern BK.

The second wavelength conversion layer WCL2 may be a wavelength conversion pattern that converts or shifts the peak wavelength of incident light into light of another peak wavelength to emit the light. For example, as described above, the emission light LE provided from the second light emitting element may be mixed light and may pass through the second wavelength conversion layer WCL2 and the second filtering pattern area 322a of the second color filter 322 and be converted into red light having a peak wavelength in a range of about 510 nm to about 550 nm to be emitted to the outside of the display device 1. In other words, the second emission light L2 passing through the second transmission area TA2 in the second emission area EA2 and emitted to the outside may be green light.

The second wavelength conversion layer WCL2 may include the base resin 330, the light scatterer 331 dispersedly disposed in the base resin 330, and a second wavelength shifter 333 dispersedly disposed in the base resin 330.

The second wavelength shifter 333 may convert or shift the peak wavelength of incident light to another peak wavelength. The second wavelength shifter 333 may convert the emission light LE provided from the second light emitting element into green light having a single peak wavelength in a range of about 510 nm to about 550 nm and emit the light. In one embodiment, the second wavelength shifter 333 may be a quantum dot, a quantum rod, or a fluorescent substance, but is not limited thereto. The case where the second wavelength shifter 333 is a quantum dot has substantially the same configuration as the case where the first wavelength shifter 332 is a quantum dot as described above, and thus a description thereof will be omitted.

Some of the emission light LE provided from the second light emitting element may pass through the second wavelength conversion layer WCL2 and be emitted without being converted into green light by the second wavelength shifter 333. Among the emission light LE, blue light in the component whose wavelength is not converted by the second wavelength conversion layer WCL2 and is incident on the second filtering pattern area 322a of the second color filter 322 may be blocked by the second filtering pattern area 322a. On the other hand, among the emission light LE, green light converted by the second wavelength conversion layer WCL2 may pass through the second filtering pattern area 322a and be emitted to the outside. Further, among the emission light LE, green light in the component whose wavelength is not converted by the second wavelength conversion layer WCL2 and which is incident on the second filtering pattern area 322a of the second color filter 322 may passe through the second filtering pattern area 322a to be emitted to the outside. For example, the second emission light L2 emitted to the outside of the display device 1 through the second transmission area TA2 may be green light, and the second emission light L2 may include a component of blue light of the emission light LE converted to green light and a component of green light of the emission light LE that passes through the second wavelength conversion layer WCL2 without change.

The light transmitting layer TPL may be disposed in the space partitioned by the bank pattern BK, and may overlap the third emission area EA3 and the third transmission area TA3 in the third direction DR3. The light transmitting layer TPL may be in direct contact with the second capping layer CPL2 and the bank pattern BK.

The light transmitting layer TPL may have a light transmission pattern that transmits incident light. For example, as described above, the emission light LE provided from the third light emitting element may pass through the light transmitting layer TPL as the mixed light as described above, and blue light in the mixed light may pass through the third filtering pattern area 323a of the third color filter 323 to be emitted to the outside of the display device 1. In other words, the third emission light L3 that passes through the third transmission area TA3 in the third emission area EA3 and emitted to the outside may be blue light.

The light transmitting layer TPL may include the base resin 330 and the light scatterer 331 dispersedly disposed in the base resin 330.

The third capping layer CPL3 of the light transmitting portion 200 may be disposed on the bank pattern BK, the light transmitting layer TPL, the first wavelength conversion layer WCL1, and the second wavelength conversion layer WCL2 and may serve to prevent impurities such as moisture or air from the outside from permeating and damaging or contaminating the light transmitting layer TPL, the first wavelength conversion layer WCL1, and the second wavelength conversion layer WCL2. The third capping layer CPL3 may cover the light transmitting layer TPL, the first wavelength conversion layer WCL1, and the second wavelength conversion layer WCL2.

As described above, the filling portion 500 may be interposed between the light emitting portion 100 and the light transmitting portion 200 to fill the space between the light emitting portion 100 and the light transmitting portion 200. In one embodiment, the filling portion 500 may be in direct contact with the upper inorganic encapsulation layer TFEc of the thin film encapsulation layer of the light emitting portion 100 and the third capping layer CPL3 of the light transmitting portion 200, but is not limited thereto.

In one embodiment, the filling portion 500 may be made of a material having an extinction coefficient of substantially zero. There is a correlation between a refractive index and an extinction coefficient, and as the refractive index decreases, the extinction coefficient also decreases. In case that the refractive index is 1.7 or less, the extinction coefficient may substantially converge to zero. In one embodiment, the filling portion 500 may be made of a material having a refractive index of less than or equal to about 1.7, and thus it may be possible to prevent or minimize light provided from the self-light emitting element from being absorbed while passing through the filling portion 500. In one embodiment, the filling portion 500 may be made of an organic material having a refractive index in a range of about 1.4 to about 1.6.

FIG. 5 schematically illustrates that the display device 1 has a structure in which the light transmitting portion 200 is formed on the other side of the color filter portion 300 in the third direction DR3 and is bonded to the light emitting portion 100 through the filling portion 500, but the disclosure is not limited thereto. The display device 10 may have a structure in which the light transmitting portion 200 is formed on the light emitting portion 100, and the color filter portion 300 and the light transmitting portion 200 are bonded through the filling portion 500.

Hereinafter, a method of predicting a lifespan of the display device 1 will be described in detail.

The method of predicting a lifespan of the display device according to one embodiment may include preparing the test panel 1000 (step S10), acquiring the first deterioration data of a first color and the second deterioration data of a second color emitted from the test panel 1000 (step S20), and extracting the lifespan of each of the pixels of the display device based on the first color component ratio, the second color component ratio, the first deterioration data, and the second color deterioration data (step S30).

First, the test panel 1000 is prepared (step S10).

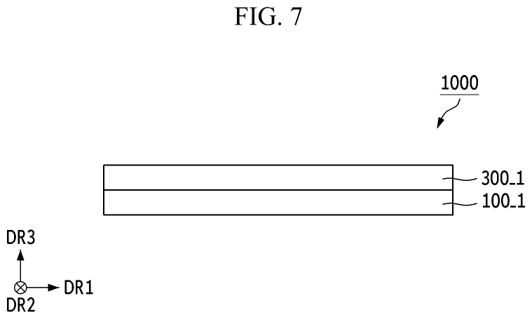

FIG. 7 is a schematic cross-sectional view illustrating the test panel 1000 according to one embodiment.

The test panel 1000 may include a light emitting portion 100_1 and a color filter portion 300_1 disposed on the light emitting portion 100_1. The description of the light emitting portion 100 described above in the display device 1 may be applied to the light emitting portion 100_1. The description of the color filter portion 300 described above in the display device 1 may be applied to the color filter portion 300_1. The test panel 1000 may not have the light transmitting portion 200 described above. In one embodiment, the test panel 1000 may include the color filter portion 300 or a color filter layer disposed on (e.g., directly disposed on) the light emitting portion 100_1.

The test light emitting panel 1000 may include multiple test light emitting elements, and each of the test light emitting elements may include a first test light emitting layer that emits a first color and a second test light emitting layer that emits a second color. The test light emitting element may be a tandem type light emitting element. In one embodiment, the test light emitting element may further include a third test light emitting layer that emits a third color different from the first color and the second color.

In one embodiment, the light emitting portion 100_1 of the test panel 1000 and the light emitting portion 100 of the display device 1 may be the same, and the test light emitting element of the test panel 1000 and the light emitting element of the display device 1 may be the same. The test light emitting element may include multiple first test light emitting layers, and the first test light emitting layers may overlap each other. The light emitting layer of the light emitting element of the display device 1 may include multiple light emitting layers or stacks that emit the light of the first color, and the light emitting layers or the stacks that emit the light of the first color may overlap each other. The number of the first test light emitting layers included in the test light emitting element may be equal to the number of the light emitting layers or stacks, which emit the light of the first color, included in the light emitting layer of the light emitting element.

The luminance of the first color and the luminance of the second color of the test panel may be measured during the measurement period to acquire the first deterioration data of the first color and the second deterioration data of the second color (step S20).

The first deterioration data may be obtained by disposing a color filter of the first color on the test light emitting element and measuring the luminance that changes during the measurement period. The second deterioration data may be obtained by disposing a color filter of the second color on the test light emitting element and measuring the luminance that changes during the measurement period.

In the specification, the deterioration data may indicate the rate at which luminance changes during aging time or measurement time, and may be shown in a graph illustrating luminance maintenance rate versus time (hr). In other words, the deterioration data may be shown in a graph where the X-axis is time (hr) and the Y-axis is the luminance maintenance rate. The luminance maintenance rate may indicate the ratio of the luminance at the corresponding time to an initial luminance at an initial time, and the luminance maintenance rate may be a positive number of 1 or less. In the specification, the lifespan may indicate the time at which the luminance maintenance rate in the deterioration data becomes a certain ratio (e.g., 0.5) or below.

The measurement period may be 400 hours, 500 hours, or more. By driving the test panel during the measurement period, the first deterioration data of the first color and the deterioration data of the second color may be obtained. The acquisition of the first deterioration data and the second deterioration data may be obtained through experiment or evaluation. The deterioration data may be obtained by a luminance meter PR650, SM-208, or Minolta Cs-1000A, but the disclosure is not limited thereto.

By disposing the third color filter layer 323 overlapping one of the test light emitting elements and disposing the second color filter layer 322 overlapping another one of the test light emitting elements on the test light emitting elements of the test light emitting panel 1000, the first deterioration data and the second deterioration data may be obtained at the same time. The disclosure is not limited thereto, and the first deterioration data and the second deterioration data may be obtained separately.

The first deterioration data and the second deterioration data obtained may vary depending on the driving conditions (voltage, current density, or the like) of the test light emitting panel 1000. Even for the same test light emitting elements, in case that different driving conditions are applied, the first deterioration data and the second deterioration data that are different may be obtained. For example, in case that the same light emitting elements are disposed in the first to third pixels and the driving conditions of the first to third pixels are different, the first deterioration data and the second deterioration data obtained may be different for each pixel.

In case that the test light emitting element further includes a third test light emitting layer, third deterioration data for the third color may also be acquired, similarly to the acquisition of the first deterioration data and the second deterioration data.

The lifespan of each of the pixels of the display device may be calculated (step S30).

The target of the lifespan calculation in step S30 may be the display device 1, which, unlike the test panel 1000, may include the light transmitting portion 200 between the light emitting portion 100 and the color filter portion 300. The lifespan may be calculated for each pixel of the display device 1. In an embodiment, the lifespan may be calculated based on the first deterioration data and the second deterioration data obtained from the test panel 1000, and the first color component ratio and the second color component ratio of the emission light emitted from each pixel of the display device 1.

The emission light LE emitted from the light emitting portion 100 may be mixed light and may include the first component light LE1 of the first color and the second component light LE2 of the second color. As the emission light LE passes through the light transmitting portion 200 and the color filter portion 300, the emission light LE may be separated into the first emission light L1, the second emission light L2, and the third emission light L3 and be emitted. Each of the emission lights L1, L2, and L3 may include a component derived from the first component light LE1 and a component derived from the second component light LE2. The ratio of the intensity/luminance of the component derived from the first component light LE1 with respect to the intensity/luminance of each of the emission lights L1, L2, and L3 may be referred to as the first color component ratio, and the ratio of the intensity/luminance of the component derived from the second component light LE2 with respect to the intensity/luminance of each of the emission lights L1, L2, and L3 may be referred to as the second color component ratio. For example, the first color component ratio and the second color component ratio may be different for each pixel.

The first color component ratio and the second color component ratio may be preset values for each thickness of the light transmitting member WCL1, WCL2, and TPL. As the thicknesses of the first wavelength conversion layer WCL1 and the second wavelength conversion layer WCL2 decreases, the ratio in which light passes through the wavelength conversion layer without change becomes greater than the ratio in which light is converted by the wavelength conversion shifters 332 and 333, so that the first color component ratio of the first emission light and the second emission light may decrease, and the second color component ratio may increase. On the other hand, as the thickness of the light transmitting layer TPL decreases, the first color component ratio of the third emission light may increase, and the second color component ratio may decrease.

The first color component ratio and the second color component ratio in each of the emission lights L1, L2, and L3 may be determined by the light transmitting portion 200 and the color filter portion 300. Material characteristics of the base resin and the colorant of the color filter layers 321, 322, and 323, and the base resin 330, the light scatterer 331, and the wavelength conversion shifters 332 and 333 included in the light transmitting member WCL1, WCL2, and TPL may be reflected in the first color component ratio and the second color component ratio. Structural characteristics such as the distance between the transmission areas TA1, TA2, and TA3, the thicknesses of the color filter layers 321, 322, and 323, and the thickness of the light transmitting member WCL1, WCL2, and TPL may also be reflected in the first color component ratio and the second color component ratio.

The first color component ratio and the second color component ratio may be different for each of the pixels PX1, PX2, and PX3 or for each of the emission lights L1, L2, and L3. The first emission light of the third color may have a higher first color component ratio and a lower second color component ratio than the second emission light of the second color. The first emission light of the third color may have a lower first color component ratio and a higher second color component ratio than the third emission light of the first color. The second emission light of the second color may have a lower first color component ratio and a higher second color component ratio than the third emission light of the first color.

Each of the first color component ratio and the second color component ratio of the first to third emission lights L1, L2, and L3 may be a positive number less than 1. The sum of the first color component ratio and the second color component ratio may be 1.

The lifespan of each pixel/emission light may be calculated based on the first color component ratio and the second color component ratio of the emission light of preset values, and the first deterioration data and the second deterioration data obtained through experiment/evaluation. The correction deterioration data of the display device 1 including the light emitting portion 100, the light transmitting portion 200, and the color filter portion 300 may be calculated by the first color component ratio and the second color component ratio reflecting the information of the light transmitting portion 200 and the color filter portion 300, and the first deterioration data and the second deterioration data reflecting the information of the light emitting portion 100.

The correction deterioration data may be calculated for each pixel or for each emission light. The correction deterioration data may be a sum of a value obtained by multiplying the luminance maintenance rate of the first color by the first color component ratio and a value obtained by multiplying the luminance maintenance rate of the second color by the second color component ratio at each time. In other words, in a deterioration data graph in which the X-axis is time (hr) and the Y-axis is the luminance maintenance rate, a graph in which the line segment between the luminance maintenance rate of the first deterioration data and the luminance maintenance rate of the second deterioration data (the luminance maintenance rate of the first color>the luminance maintenance rate of the second color) is divided into the second color component ratio and the first color component ratio at the identical time may be referred to as the correction deterioration data. In one embodiment, the correction deterioration data for each pixel may be calculated using Equation 1:

$$\begin{matrix}[ Equation 1 ] & \\ {L}_{EX} = {L}_{C 1} \times {M}_{1} + {L}_{C 2} \times {M}_{2} & ( 1 )\end{matrix}$$

In Equation 1, L_{EX} may be a corrected luminance maintenance rate of the pixel, L_{C1} may be a luminance maintenance rate in the first deterioration data, L_{C2} may be a luminance maintenance rate in the second deterioration data, M₁ may be a preset first color component ratio of the emission light, and M₂ may be a preset second color component ratio of the emission light.

From the correction deterioration data obtained as described above, the time at which the luminance maintenance rate falls below a preset certain ratio (e.g., 0.5) may be determined as the lifespan.

Thereafter, the lifespan of each pixel of the display device 1 may be calculated by repeating the above process by varying the thickness of the light transmitting member WCL1, WCL2, and TPL of the light transmitting portion 200. As the thickness of the light transmitting member WCL1, WCL2, and TPL varies, the preset values of the first component ratio and the second component ratio may change. The display device 1 may be manufactured by selecting an optimal lifespan among the calculated lifespans. The lifespan may be predicted without manufacturing a sample in which the light transmitting portion 200 is varied. The display device 1 including the light transmitting portion 200 with a thin thickness may be manufactured without taking a lot of time for sample production and lifespan evaluation.

Further, the afterimage of each pixel may be corrected through the correction deterioration data without conducting actual lifespan evaluation.

In case that the test light emitting element further includes the third test light emitting layer, for the lifespan calculation of the display device 1, not only the first deterioration data and the second deterioration data but also the third deterioration data may be reflected, and the preset third color component ratio may also be reflected.

Hereinafter, in order to describe the disclosure, an embodiment will be given and described in detail. However, the embodiments of the specification may be modified in various other forms, and the scope of the application is not to be construed as being limited to the embodiments described in detail below. The embodiments of the application are provided to more completely describe the specification to those with average knowledge in the art.

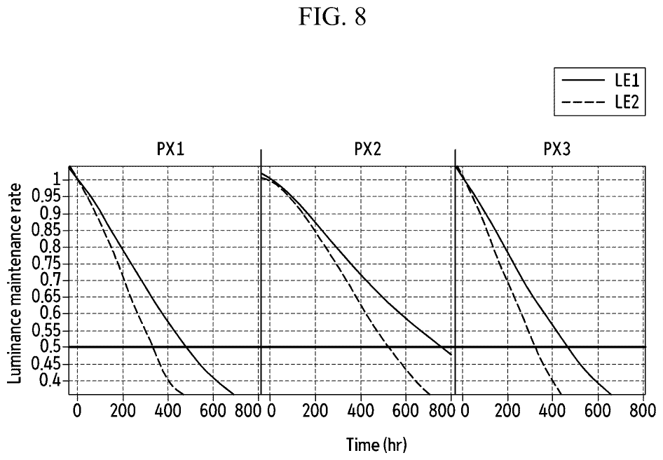

FIG. 8 is a graph showing first deterioration data and second deterioration data in the first to third pixels PX1, PX2, and PX3 of the test panel 1000 according to one embodiment.

The test light emitting element of the test panel 1000 measured in FIG. 8 may include the same structure as the light emitting layer OL of FIG. 6, the first to third light emitting layers EML1, EML2, and EML3 of the first to third stacks ST1, ST2, and ST3 may emit blue light, and the fourth light emitting layer EML4 of the fourth stack ST4 may emit green light.

A test panel is obtained by disposing a blue color filter and a green color filter on the test light emitting element 1000. While the test panel is driven for 800 hours, a luminance is measured for the emission light LE1 of a blue color and the emission light LE2 of a green color, and a graph (FIG. 8) of the luminance maintenance rate as compared with the initial luminance, for example, the first deterioration data and the second deterioration data, is obtained. Since the current densities applied to the first to third pixels PX1, PX2, and PX3 are different, the first deterioration data and the second deterioration data obtained from the first to third pixels PX1, PX2, and PX3 are different.

A calculation process is performed to obtain the correction deterioration data of the display device 1 including the light transmitting portion 200. The display device 1 may have the same structure as illustrated in FIG. 5, and the light emitting portion 100 of the display device 1 may be the same as the light emitting portion 100_1 of the test light emitting panel.

The first component ratio and the second component ratio that are preset according to the thicknesses of the first wavelength conversion layer WCL1, the second wavelength conversion layer WCL2, and the light transmitting layer TPL of the light transmitting member are illustrated in Table 1 below. Referring to Table 1 below, it may be seen that the second component ratio (green light) in the third pixel that emits blue light is higher than 0 because the blue color filter passes a part in the green wavelength area.

TABLE 1

Emission light

| | Red | Green | Blue |
|---|---|---|---|
| | light | light | light |
| | (first | (second | (third |
| | pixel) | pixel) | pixel) |
| Thickness (μm) of light transmitting | 9 | 9 | 9 |
| member | | | |
| Sum of component ratios | 1.000 | 1.000 | 1.000 |
| First component ratio (blue light) | 0.527 | 0.422 | 0.846 |
| Second component ratio (green light) | 0.473 | 0.578 | 0.154 |
| Thickness (μm) of light transmitting | 7 | 7.6 | 6 |
| member | | | |
| Sum of component ratios | 1.000 | 1.000 | 1.000 |
| First component ratio (blue light) | 0.509 | 0.401 | 0.864 |
| Second component ratio (green light) | 0.491 | 0.599 | 0.136 |
| Thickness (μm) of light transmitting | 5 | 5 | 5 |
| member | | | |
| Sum of component ratios | 1.000 | 1.000 | 1.000 |
| First component ratio (blue light) | 0.467 | 0.347 | 0.873 |
| Second component ratio (green light) | 0.533 | 0.653 | 0.127 |

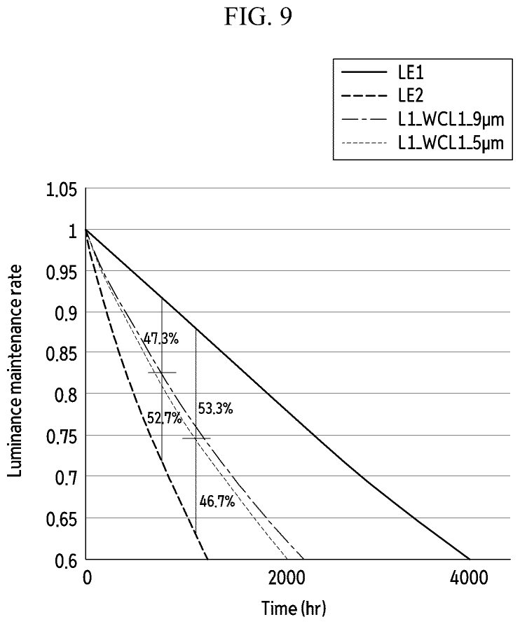

FIG. 9 is a graph showing correction deterioration data in the first pixel PX1. For simplicity of description, obtaining the correction deterioration data for each pixel will be described using the first pixel PX1 as an example.

Referring to FIG. 9, the first deterioration data of the first component light LE1 and the second deterioration data of the second component light LE2 acquired from the first pixel PX1 of the test light emitting element are illustrated. Referring to Table 1, in case that the thickness of the first wavelength conversion layer WCL1 corresponding to the first emission light (red light) of the first pixel is 9 μm, it may be seen that the first component ratio is 0.527 and the second component ratio is 0.473. Further, in case that the thickness of the first wavelength conversion layer WCL1 corresponding to the first emission light (red light) of the first pixel is 5 μm, it may be seen that the first component ratio is 0.467 and the second component ratio is 0.533.

In order to obtain correction deterioration data L1_WCL1_9 μm in case that the thickness of the first wavelength conversion layer WCL1 is 9 μm, a value obtained by multiplying the luminance maintenance rate of the first deterioration data LE1 by 0.527 may be added to a value obtained by multiplying the luminance maintenance rate of the second deterioration data LE2 by 0.473. For example, a point in which the Y-axis values of the first deterioration data LE1 and the second deterioration data LE2 are divided into 47.3% vs. 52.7% may be the correction deterioration data L1_WCL1_9 μm.

In case that the thickness of the first wavelength conversion layer WCL1 is changed to 5 μm, a value obtained by multiplying the luminance maintenance rate of the first deterioration data LE1 by 0.467 may be added to a value obtained by multiplying the luminance maintenance rate of the second deterioration data LE2 by 0.533 to calculate correction deterioration data L1_WCL1_5 μm. The correction deterioration data L1_WCL1_5 μm may be a point in which the Y-axis values of the first deterioration data LE1 and the second deterioration data LE2 are divided into 53.3% vs. 46.7%.

The first pixel PX1 has been described in detail using FIG. 9 as an example, but multiple correction deterioration data may be obtained by repeating the same process and varying the thickness of the light transmitting member WCL1, WCL2, and TPL for the second pixel PX2 and the third pixel PX3. From the correction deterioration data, the time that the luminance maintenance rate is 0.5 may be determined as the lifespan of the pixel.

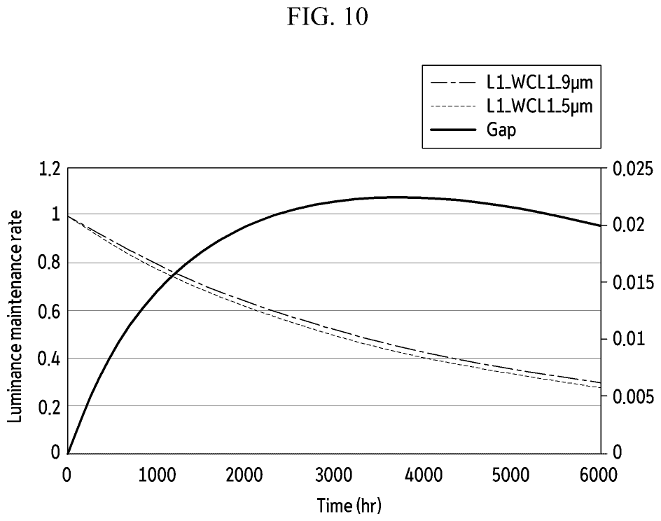

FIG. 10 is a graph showing a comparison between the correction deterioration data of FIG. 9, which compares the case where the first wavelength conversion layer WCL1 is 9 μm (L1_WCL1_9 μm) with the case where the first wavelength conversion layer WCL1 is 5 μm (L1_WCL1_5 μm), and shows a gap between the luminance maintenance rates between the two. Although the thickness of the first wavelength conversion layer WCL1 of the display device 1 is set to 9 μm, and the thickness of the first wavelength conversion layer WCL1 is changed to 5 μm, it may be confirmed that the difference in the luminance maintenance rates of the first pixel is small. Through the method of predicting a lifespan of the display device 1 according to one embodiment of the disclosure, it may be possible to find a thickness with an optimal lifespan without having to manufacture a sample for each thickness change of the wavelength conversion layers WCL1, WCL2, and TPL and perform a lifespan evaluation of 500 hours or more.

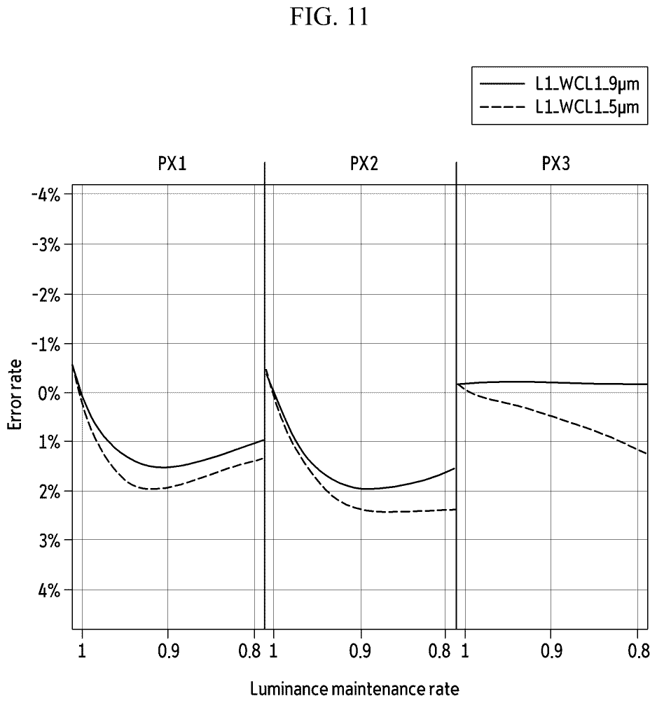

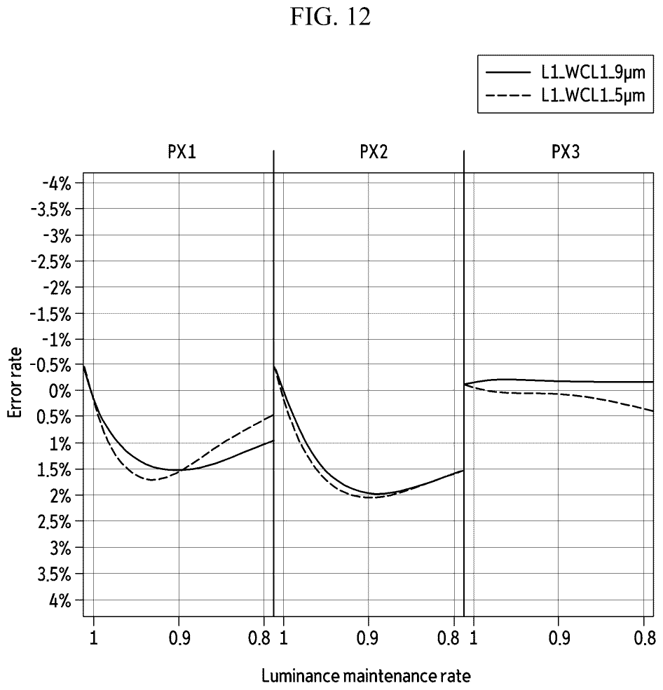

FIG. 11 is a graph showing a lifespan error rate of the display device 1 in which the correction deterioration data is not reflected, and FIG. 12 is a graph showing a lifespan error rate of the display device 1 in which afterimages are corrected through the correction deterioration data.

In case that the display device 1 including the light emitting portion 100, the light transmitting portion 200, and the color filter portion 300 is manufactured, the luminance maintenance rate obtained by measuring a luminance for each time may be displayed, and a curved linear graph may be obtained. By averaging adjacent points, gradual linear deterioration data may be obtained. The difference between the deterioration data and the actual lifespan and time value of the display device 1 may be referred to as the lifespan error rate.

In FIGS. 11 and 12, the lifespan error rate of the display device 1 with a wavelength conversion layer of 9 μm is indicated by a solid line. The dotted line in FIG. 11 relates to a display device 1 with a wavelength conversion layer of 5 μm, and the correction deterioration data of the method of predicting a lifespan is not reflected. The dotted line in FIG. 12 relates to a display device 1 with a wavelength conversion layer of 5 μm, and the afterimage is corrected through the correction deterioration data of 5 μm obtained through the method of predicting a lifespan according to the embodiment.

In FIG. 11, the first emission light L1 emitted from the first pixel PX1 has an error rate of up to 2%, the second emission light L2 emitted from the second pixel PX2 has an error rate of about 2.5%, and the third emission light L3 emitted from the third pixel PX3 has an error rate exceeding 1%.

On the other hand, in FIG. 12, the first emission light L1 emitted from the first pixel PX1 has an error rate of about 1.7%, the second emission light L2 emitted from the second pixel PX2 has an error rate of about 2%, and the third emission light L3 emitted from the third pixel PX3 has an error rate within 0.5%. Through the method of predicting a lifespan according to one embodiment, it may be seen that the error rate of the display device 1 in which the afterimage is corrected through the correction deterioration data is small. It may be possible to find an optimal thickness that exhibits an equivalent luminance to a case where the thickness of the wavelength conversion layer is large (9 μm).

The display device according to one embodiment of the present disclosure can be applied to various electronic devices. The electronic device according to the one embodiment of the present disclosure includes the display device described above, and may further include modules or devices having additional functions in addition to the display device.

FIG. 13 is a block diagram of an electronic device according to one embodiment of the present disclosure.

Referring to FIG. 13, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

FIG. 14 is a schematic diagram of an electronic device according to various embodiments of the present disclosure.

Referring to FIG. 14, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of predicting a lifespan of a display device, comprising:
preparing a test panel comprising a test light emitting element comprising a first test light emitting layer which emits light of a first color and a second test light emitting layer which emits light of a second color different from the first color;
measuring a luminance of the light of the first color and a luminance of the light of the second color of the test panel during a measurement period to acquire first deterioration data of the first color and second deterioration data of the second color;
calculating a lifespan of a first pixel of a display device different from the test panel based on the first deterioration data, the second deterioration data, and a first color component ratio and a second color component ratio of first emission light for a thickness of a first wavelength conversion layer,
wherein the first pixel of the display device comprises a first light emitting element which emits the first emission light and mixed light of the first color and the second color, and the first wavelength conversion layer overlapping the first light emitting element in a thickness direction, and
a light emitting layer of the first light emitting element comprises a first light emitting layer which emits light of the first color, and a second light emitting layer which emits light of the second color and overlaps the first light emitting layer in the thickness direction.

2. The method of claim 1, wherein
the test light emitting element comprises a plurality of first test light emitting layers overlapping each other in the thickness direction,
the light emitting layer of the first light emitting element comprises a plurality of first light emitting layers overlapping each other in the thickness direction, and
a number of the plurality of first test light emitting layers comprised in the test light emitting element and a number of the plurality of first light emitting layers comprised in the light emitting layer of the first light emitting element are equal.

3. The method of claim 1, wherein the first color is blue and the second color is green or red.

4. The method of claim 1, wherein
the test light emitting element further comprises a third test light emitting layer which emits light of a third color different from the first color and the second color,
the first light emitting element emits mixed light of the first color, the second color, and the third color,
the light emitting layer of the first light emitting element further comprises a third light emitting layer which emits light of the third color, and
the first color is blue, the second color is green, and the third color is red.

5. The method of claim 1, wherein each of the first color component ratio and the second color component ratio of the first emission light is less than 1.

6. The method of claim 5, wherein a sum of the first color component ratio and the second color component ratio of the first emission light is 1.

7. The method of claim 1, wherein as the thickness of the first wavelength conversion layer decreases, the first color component ratio of the first emission light decreases.

8. The method of claim 1, wherein the first color component ratio and the second color component ratio of the first emission light are determined by a wavelength conversion shifter of the first wavelength conversion layer and a color filter disposed on the first wavelength conversion layer.

9. The method of claim 1, wherein the measuring of the luminance of the light of the first color and the luminance of the light of the second color of the test panel during the measurement period to acquire the first deterioration data of the first color and the second deterioration data of the second color comprises:
disposing a color filter of the first color on the test light emitting element and measuring a luminance of the light of the first color that changes during the measurement period to acquire the first deterioration data which is a luminance maintenance rate compared to an initial luminance of the light of the first color; and
disposing a color filter of the second color on the test light emitting element, and measuring a luminance of the light of the second color that changes during the measurement period to acquire the second deterioration data which is a luminance maintenance rate compared to an initial luminance of the light of the second color.

10. The method of claim 1, wherein the calculating of the lifespan of the first pixel of the display device comprises:
calculating correction deterioration data using Equation 1:
$${L}_{EX} = {L}_{C 1} \times {M}_{1} + {L}_{C 2} \times {M}_{2} \qquad [ Equation 1 ]$$
wherein L_{EX} is a corrected luminance maintenance rate of the first pixel, L_{C1} is a luminance maintenance rate in the first deterioration data, L_{C2} is a luminance maintenance rate in the second deterioration data, M₁ is the first color component ratio of the first emission light, and M₂ is the second color component ratio of the first emission light; and
determining, from the correction deterioration data, a time at which the luminance maintenance rate falls below a preset ratio as the lifespan of the first pixel.

11. The method of claim 1, further comprising:
calculating lifespans of the first pixel of the display device by varying the thickness of the first wavelength conversion layer; and
selecting an optimal lifespan among the lifespans of the first pixel.

12. The method of claim 1, wherein
the light emitting layer of the first light emitting element comprises a first hole transport layer, a first stack in which the first light emitting layer and a first electron transport layer are sequentially disposed, and a second stack in which a second hole transport layer, the second light emitting layer and a second electron transport layer are sequentially disposed, and
the first stack and the second stack overlap each other in the thickness direction.

13. The method of claim 12, wherein
the light emitting layer of the first light emitting element comprises a plurality of first stacks, and
the plurality of first stacks and the second stack overlap each other in the thickness direction.

14. The method of claim 1, further comprising:
calculating a lifespan of a second pixel of the display device based on the first deterioration data, the second deterioration data, and the first color component ratio and the second color component ratio of second emission light for a thickness of a second wavelength conversion layer,
wherein the second pixel of the display device comprises a second light emitting element which emits the second emission light and mixed light of the first color and the second color, and a second wavelength conversion layer overlapping the second light emitting element in the thickness direction.

15. The method of claim 14, wherein the second color component ratio of the second emission light is greater than the second color component ratio of the first emission light.

16. The method of claim 14, further comprising:
calculating a lifespan of a third pixel of the display device based on the first deterioration data, the second deterioration data, and the first color component ratio and the second color component ratio of third emission light for a thickness of a light transmitting layer,
wherein the third pixel of the display device comprises a third light emitting element which emits the third emission light and mixed light of the first color and the second color, and the light transmitting layer overlapping the third light emitting element in the thickness direction.

17. The method of claim 16, wherein the second color component ratio of the third emission light is smaller than the second color component ratio of the first emission light.

18. The method of claim 16, wherein
the first wavelength conversion layer includes a first base resin and a first wavelength conversion shifter,
the second wavelength conversion layer includes a second base resin and a second wavelength conversion shifter, and
the light transmitting layer includes a third base resin.

19. The method of claim 16, wherein
the display device comprises a first color filter disposed on the first wavelength conversion layer, a second color filter disposed on the second wavelength conversion layer, and a third color filter disposed on the light transmitting layer,
the first color filter passes light of a third color different from the first color and the second color,
the second color filter passes the light of the second color, and
the third color filter passes the light of the first color.

20. The method of claim 19, wherein the first emission light comprises:
a component of light converted from the light of the first color, which passes through the first color filter; and
a component of the light of the second color, which passes through the first color filter.

21. An electronic comprising:
at least one display device including a substrate having cross-repeated planar and tower areas; and
at least one of a display module, a processor, a memory, and a power module connected to the display device,
a method of predicting a lifespan of the display device, comprising: preparing a test panel comprising a test light emitting element comprising a first test light emitting layer which emits light of a first color and a second test light emitting layer which emits light of a second color different from the first color;
measuring a luminance of the light of the first color and a luminance of the light of the second color of the test panel during a measurement period to acquire first deterioration data of the first color and second deterioration data of the second color;
calculating a lifespan of a first pixel of a display device different from the test panel based on the first deterioration data, the second deterioration data, and a first color component ratio and a second color component ratio of first emission light for a thickness of a first wavelength conversion layer,
wherein the first pixel of the display device comprises a first light emitting element which emits the first emission light and mixed light of the first color and the second color, and the first wavelength conversion layer overlapping the first light emitting element in a thickness direction, and
a light emitting layer of the first light emitting element comprises a first light emitting layer which emits light of the first color, and a second light emitting layer which emits light of the second color and overlaps the first light emitting layer in the thickness direction.
